(19) United States
(12) Patent Application Publication
(10) Pub. No.: US 2018/0267083 A1
(43) Pub. Date: Sep. 20, 2018

(54) MICROELECTROMECHANICAL PROBE AND PROBE HEAD HAVING THE SAME

(71) Applicant: MPI CORPORATION, CHU-PEI CITY (TW)

(72) Inventors: Shao-Lun WEI, CHU-PEI CITY (TW); Yu-Chen HSU, CHU-PEI CITY (TW); Mao-Fa SHEN, CHU-PEI CITY (TW); Neng-Hsuan KUO, CHU-PEI CITY (TW); Chien-Yu LIN, CHU-PEI CITY (TW); Ching-Kai CHU, CHU-PEI CITY (TW)

(21) Appl. No.: 15/921,214

(22) Filed: Mar. 14, 2018

(30) Foreign Application Priority Data
Mar. 14, 2017 (TW) 106108306
Mar. 2, 2018 (TW) 107106922

(51) Int. Cl. G01R 1/067

(52) U.S. Cl. CPC G01R 1/06727

(57) ABSTRACT

A microelectromechanical probe has tail, head and body portions, and includes a pinpoint layer having a planarized top surface where a structural layer having first and second sides, a cutting face and a front terminal surface adjoining the first and second sides is disposed. The cutting face descends from the top surface of the structural layer toward the pinpoint layer to the front terminal surface. The front terminal surface extends from a front end of the cutting face to the top surface of the pinpoint layer. The pinpoint layer has a pinpoint protruding over the front terminal surface and located at the head portion. Within the head portion, the pinpoint layer is greater in hardness and less in electrical conductivity than the structural layer. The probe makes small probing marks, is highly recognizable in an automatic pinpoint recognition process, and can be conveniently installed.

### BACKGROUND OF THE INVENTION

### 1. Field of the Invention

The present invention relates generally to a probe used in a probe card for probing a device under test (hereinafter referred to as “DUT”), and more particularly to a microelectromechanical probe, a manufacturing method thereof, and a probe head having the microelectromechanical probe.

### 2. Description of the Related Art

FIG. 1 shows a conventional buckling probe 10, namely cobra probe, which is manufactured by a microelectromechanical system manufacturing process (hereinafter referred to as “MEMS manufacturing process”). In the manufacturing process, the buckling probe 10 is formed on a substrate (not shown) with a lying posture on the substrate. Specifically speaking, before the buckling probe 10 is completely formed, a photoresist layer is formed on the substrate and then defined by a photomask and developed with a hollow pattern by photolithography technique in a way that the hollow pattern of the photoresist layer has a shape corresponding to the shape of front and rear surfaces 11, 12 of the probe 10. Thereafter, the probe 10 is formed in the hollow pattern of the photoresist layer by electroplating. When being completely formed, the probe 10 lies on the substrate in a way that the front and rear surfaces 11, 12 of the probe 10 are parallel to the substrate.

Compared with the traditional machining process, the aforesaid MEMS manufacturing process is faster, more favorable for batch and mass production and more precise in manufacturing the probe 10. However, the MEMS manufacturing process causes a restriction on the shape of the probe 10. That is, the pinpoint portion 13 of the probe 10 can taper off by only left and right sides 131, 132 thereof inclining to approach each other, but front and rear sides 133, 134 of the pinpoint portion 13 are hard to be made inclining to approach each other. Therefore, the pinpoint portion 13 has an elongated probing end 135 with a certain surface area for contacting the DUT. The probing end 135 is simply depicted as a straight line in FIG. 1. Actually, the probing end 135 is shaped as an elongated arc surface with a certain width. Such probing end 135 has disadvantages of making relatively larger probing marks on the DUT and having less recognizable image in the automatic pinpoint recognition process. Besides, the probing end 135 may be not sharp enough to pierce through the passivation layer on the surface of the DUT, causing undesired faults or errors in testing the DUT. If the probe 10 is applied with a relatively larger force to make sure that the probing end 135 can always pierce through the passivation layer to probe the DUT, this approach will cause heavy wear to the probe 10 and shorten the service life of the probe 10.

### SUMMARY OF THE INVENTION

The present invention has been accomplished in view of the above-noted circumstances. It is an objective of the present invention to provide a microelectromechanical probe, the probing end of which for contacting the DUT has small area, thereby making small probing marks upon probing the DUT, easily piercing through the passivation layer of the DUT, and highly recognizable in the automatic pinpoint recognition process.

To attain the above objective, the present invention provides a microelectromechanical probe which is provided with a tail portion, a head portion, and a body portion connecting the tail portion and the head portion. The microelectromechanical probe includes a pinpoint layer and a structural layer. The pinpoint layer has a top surface which is processed by planarization. The structural layer is disposed on the top surface of the pinpoint layer and provided with a top surface in a way that the top surface of the structural layer and the top surface of the pinpoint layer substantially face a same direction, a first side and a second side both adjoining the top surface of the structural layer, and a cutting face and a front terminal surface both adjoining the first side and the second side. The cutting face descends from the top surface of the structural layer toward the pinpoint layer to the front terminal surface. The cutting face has a front end which is located nearest the top surface of the pinpoint layer within the cutting face. The front terminal surface is extended from the front end of the cutting face to the top surface of the pinpoint layer. The pinpoint layer has a pinpoint protruding over the front terminal surface of the structural layer and located at the head portion. Besides, within the head portion of the microelectromechanical probe, the pinpoint layer has a hardness greater than that of the structural layer, and the structural layer has an electrical conductivity greater than that of the pinpoint layer.

As a result, the pinpoint layer can be made with a small thickness accompanying a small area of the probing end of the pinpoint for contacting the DUT, but the microelectromechanical probe still has high structural strength because of having not only the pinpoint layer but also the structural layer. In this way, the microelectromechanical probe makes small probing marks upon probing the DUT, easily pierces through the passivation layer of the DUT, and has high recognizability in the automatic pinpoint recognition process. Besides, the top surface of the pinpoint layer is processed by planarization, so the pinpoint layer is not only uniform in thickness, but also prevented from burr edge produced on the probing end of the pinpoint. During batch production of the microelectromechanical probe by the MEMS manufacturing process, which means in such process a plurality of microelectromechanical probes are manufactured at the same time, after the pinpoint layers of the microelectromechanical probes are formed, the top surfaces thereof can be processed by planarization at the same time. In this way, the pinpoints of the microelectromechanical probes are equal in thickness. Therefore, when the microelectromechanical probes are installed in the probe card to perform the testing work, they make uniform probing marks. Besides, during the automatic pinpoint recognition process, the cutting face is effective in light extinction by scattering the light emitted to the cutting face, so that the light reflected by the pinpoint is relatively more obvious. Therefore, the cutting face can improve the image recognition of the pinpoint. On the other hand, when the microelectromechanical probe is inserted through the installing hole of the dies of the probe seat, the cutting face can perform the guiding function, thereby improving the convenience of the probe installation. As to the front terminal surface provided between the front end of the cutting face and the top surface of the pinpoint layer, it refers to a distance reserved between the front end of the cutting face and the top surface of the pinpoint layer when the cutting face is formed by the cutting process, so that the front end of the cutting face doesn't directly adjoin the top surface of the pinpoint layer. This feature can increase the structural strength of the probe and extend electrical conductive effect without affecting the image recognition of the pinpoint.

The present invention further provides a probe head having the aforesaid microelectromechanical probe, which includes an upper die, a lower die and an aforesaid microelectromechanical probe. The tail portion and the head portion of the microelectromechanical probe are inserted through the upper die and the lower die respectively in a way that the pinpoint and the cutting face are both completely exposed out of the lower die.

The present invention further provides a method of manufacturing the aforesaid microelectromechanical probe. The microelectromechanical probe has a tail portion, a head portion, and a body portion connecting the tail portion and the head portion. The method includes the steps of:

a) forming a pinpoint layer on a substrate by a MEMS manufacturing process in a way that the pinpoint layer has a bottom surface facing the substrate and a top surface substantially opposite to the bottom surface;

b) processing the top surface of the pinpoint layer by planarization;

c) forming a structural layer on the top surface of the pinpoint layer by another MEMS manufacturing process in a way that a top surface of the structural layer and the top surface of the pinpoint layer substantially face a same direction; the structural layer has a first side and a second side both adjoining the top surface of the structural layer, and a front terminal surface adjoining the top surface of the structural layer, the first side and the second side; the pinpoint layer has a pinpoint protruding over the front terminal surface of the structural layer and located at the head portion; besides, within the head portion of the microelectromechanical probe, the pinpoint layer has a hardness greater than that of the structural layer, and the structural layer has an electrical conductivity greater than that of the pinpoint layer; and

d) cutting the structural layer from the first side to the second side by a cutting tool which is one of a ball nose milling cutter, an abrasive wheel, a form grinding wheel, a single-tooth milling cutter and a multi-tooth milling cutter, so as to simultaneously provide a cutting face and reduce the area of the top surface of the structural layer and the area of the front terminal surface in a way that the cutting face descends from the top surface of the structural layer toward the pinpoint layer to the front terminal surface, and the front terminal surface is extended from a front end of the cutting face, which is located nearest the top surface of the pinpoint layer within the cutting face, to the top surface of the pinpoint layer.

To attain the above objective, the present invention provides another microelectromechanical probe provided with a tail portion, a head portion, and a body portion connecting the tail portion and the head portion. The microelectromechanical probe includes a pinpoint layer, a structural layer, and a cutting face. The pinpoint layer has a top surface processed by planarization, a bottom surface substantially opposite to the top surface, a first side and a second side both adjoining the top surface and the bottom surface, and a probing end surface adjoining the first side and the second side and located at the head portion. The structural layer is disposed on the top surface of the pinpoint layer and provided with a top surface in a way that the top surface of the structural layer and the top surface of the pinpoint layer substantially face a same direction, and a first side and a second side both adjoining the top surface of the structural layer. The first side of the structural layer and the first side of the pinpoint layer substantially face a same direction, and the second side of the structural layer and the second side of the pinpoint layer substantially face a same direction. The cutting face adjoins the first side and the second side of the pinpoint layer and the first side and the second side of the structural layer and has a curved section and a flat section. The curved section curvedly descends from the top surface of the structural layer to the pinpoint layer and has a bottom end located at the pinpoint layer. The flat section is extended from the bottom end of the curved section substantially in parallel to the bottom surface of the pinpoint layer to the probing end surface. The pinpoint layer has a first thickness defined by the bottom surface and the top surface of the pinpoint layer, and a second thickness defined by the bottom surface of the pinpoint layer and the flat section of the cutting face. The first thickness is greater than the second thickness. The structural layer has an electrical conductivity greater than of the pinpoint layer.

As a result, the microelectromechanical probe also has the effect of the microelectromechanical probe mentioned above. Furthermore, because the pinpoint layer can be made with a small thickness and the probing end surface is located at the relatively thinner section of the pinpoint layer resulted from the cutting process, i.e. the section having the flat section of the cutting face, the microelectromechanical probe makes relatively smaller probing marks upon probing the DUT and relatively more easily pierces through the passivation layer of the DUT. Besides, the cutting face is extended from the top surface of the structural layer to the probing end surface. Therefore, except for the probing end surface, the other surface of the probe facing the light for the pinpoint recognition process is formed by the cutting process and thereby effective in light extinction, so that the recognizability of the pinpoint is relatively higher. In addition, although the pinpoint of the microelectromechanical probe is very thin because of the cutting process, the thinnest part thereof, i.e. the part having the flat section, is flat-shaped and thereby prevented from stress concentration, so that the probe is not easily fractured. In addition, the cross-section area of the part of the pinpoint layer having the flat section is constant and therefore will not be changed after the probe is cleaned or worn, thereby ensuring long service life of the probe.

The present invention further provides a probe head having the aforesaid microelectromechanical probe, which includes an upper die, a lower die, and an aforesaid microelectromechanical probe. The tail portion and the head portion of the microelectromechanical probe are inserted through an installing hole of the upper die and an installing hole of the lower die respectively. The cutting face is completely exposed out of the lower die for high recognizability of the pinpoint.

Preferably, the structural layer may include a first section and a second section made of different materials; the first section is extended from the tail portion toward the head portion and provided with a connecting end; the second section is extended from the connecting end toward the probing end surface. In this way, the first and second sections of the structural layer can be provided according to the positions thereof with the demanded characteristics by the materials thereof. For example, the second section of the structural layer can be made of the material with relatively higher hardness, like the pinpoint layer, so as to improve the structural strength of the probe. In such condition, the top and bottom ends of the installing hole of the lower die may be both located correspondingly to the second section of the structural layer, which means the inner wall of the installing hole of the lower die may completely face the second section of the structural layer, so as to reduce the wearing of the structural layer resulted from the friction between the structural layer and the inner wall of the installing hole of the lower die, thereby preventing the probe from fracture. The first section of the structural layer can still use the material with relatively higher electrical conductivity, so that the electrical conductivity of the whole structural layer is still higher than the electrical conductivity of the pinpoint layer. There may be an attachment layer disposed between the structural layer and the pinpoint layer to make the structural layer be fixed to the pinpoint layer firmly. The attachment layer and the first section of the structural layer may be made of the same material.

Preferably, the probing end surface may be archedly extended from the first side of the pinpoint layer to the second side of the pinpoint layer. In this way, when the probing end surface of the microelectromechanical probe is worn because of probing the DUT or being cleaned, the area of the probing end, i.e. the area of the part of the probing end surface contacting the DUT, is relatively less increased by the wearing of the probing end surface because the whole probing end surface is arc-shaped, so that the probing marks are relatively less widened.

The present invention further provides a method of manufacturing the aforesaid microelectromechanical probe. The microelectromechanical probe has a tail portion, a head portion, and a body portion connecting the tail portion and the head portion. The method includes the steps of:

a) forming a pinpoint layer on a substrate by a MEMS manufacturing process in a way that the pinpoint layer has a bottom surface facing the substrate, a top surface substantially opposite to the bottom surface, a first side and a second side both adjoining the top surface and the bottom surface, and a probing end surface adjoining the top surface, the bottom surface, the first side and the second side and located at the head portion;

b) processing the top surface of the pinpoint layer by planarization;

c) forming a structural layer on the top surface of the pinpoint layer by another MEMS manufacturing process in a way that a top surface of the structural layer and the top surface of the pinpoint layer substantially face a same direction; the structural layer has a first side, a second side and a front terminal surface all adjoining the top surface of the structural layer; the first side of the structural layer and the first side of the pinpoint layer substantially face a same direction, and the second side of the structural layer and the second side of the pinpoint layer substantially face a same direction; the structural layer has an electrical conductivity greater than that of the pinpoint layer; and

d) cutting the pinpoint layer and the structural layer from the first side of the pinpoint layer and the first side of the structural layer to the second side of the pinpoint layer and the second side of the structural layer by a bull nose end mill, so as to simultaneously provide a cutting face, cut off the front terminal surface of the structural layer and reduce the area of the top surface of the structural layer and the area of the probing end surface in a way that the cutting face has a curved section curvedly descending from the top surface of the structural layer to the pinpoint layer and having a bottom end located at the pinpoint layer, and a flat section extended from the bottom end of the curved section substantially parallel to the top surface of the pinpoint layer to the probing end surface; the pinpoint layer has a first thickness defined by the bottom surface and the top surface of the pinpoint layer, and a second thickness defined by the bottom surface of the pinpoint layer and the flat section of the cutting face; the first thickness is greater than the second thickness.

In this way, the curved section and the flat section of the cutting face can be simultaneously formed in the cutting process using the bull nose end mill, so the manufacturing process of the microelectromechanical probe is relatively faster because the cutting process is simple. Besides, the part of the pinpoint, which has the flat section, is uniform in thickness and therefore has no undulation or concave, thereby prevented from stress concentration, so that the probe is not easily fractured.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic perspective view of a conventional microelectromechanical probe.

FIG. 2 is a perspective view of a microelectromechanical probe according to a first preferred embodiment of the present invention.

FIG. 3 and FIG. 4 are partial front views of the microelectromechanical probe according to the first preferred embodiment of the present invention, primarily showing a tail portion and a head portion of the microelectromechanical probe respectively.

FIG. 5 is a partial lateral view of the microelectromechanical probe according to the first preferred embodiment of the present invention, showing the head portion of the microelectromechanical probe.

FIGS. 6-8 are schematic lateral views showing the manufacturing process of the microelectromechanical probe according to the first preferred embodiment of the present invention.

FIGS. 9-10 are schematic top views showing the manufacturing process of the microelectromechanical probe according to the first preferred embodiment of the present invention.

FIG. 11 is similar to FIG. 5, but showing a cutting face of the head portion of the microelectromechanical probe is shaped as a combination of two curved surfaces.

FIG. 12 is similar to FIG. 4, but showing the cutting face of the head portion of the microelectromechanical probe has a plurality of cut marks.

FIG. 13 is similar to FIG. 5, but showing the cutting face of the head portion of the microelectromechanical probe is shaped as a plane.

FIG. 14 is a perspective view of a microelectromechanical probe according to a second preferred embodiment of the present invention.

FIG. 15 and FIG. 16 are partial front views of the microelectromechanical probe according to the second preferred embodiment of the present invention, primarily showing a tail portion and a head portion of the microelectromechanical probe respectively.

FIG. 17 is a partial lateral view of the microelectromechanical probe according to the second preferred embodiment of the present invention, showing the head portion of the microelectromechanical probe.

FIG. 18 is a perspective view of a microelectromechanical probe according to a third preferred embodiment of the present invention.

FIG. 19 is a front view of the microelectromechanical probe according to the third preferred embodiment of the present invention.

FIG. 20 is a perspective view of a microelectromechanical probe according to a fourth preferred embodiment of the present invention.

FIG. 21 is a front view of the microelectromechanical probe according to the fourth preferred embodiment of the present invention.

FIG. 22 is a schematic sectional view of a probe head according to a fifth preferred embodiment of the present invention.

FIG. 23 is a perspective view of a microelectromechanical probe according to a sixth preferred embodiment of the present invention.

FIG. 24 and FIG. 25 are partial front views of the microelectromechanical probe according to the sixth preferred embodiment of the present invention, primarily showing a tail portion and a head portion of the microelectromechanical probe respectively.

FIG. 26 is a lateral view of the microelectromechanical probe according to the sixth preferred embodiment of the present invention.

FIGS. 27-31 are schematic lateral views showing the manufacturing process of the microelectromechanical probe according to the sixth preferred embodiment of the present invention.

FIGS. 32-33 are schematic top views showing the manufacturing process of the microelectromechanical probe according to the sixth preferred embodiment of the present invention.

FIG. 34 is a perspective view of a microelectromechanical probe according to a seventh preferred embodiment of the present invention.

FIG. 35 and FIG. 36 are partial front views of the microelectromechanical probe according to the seventh preferred embodiment of the present invention, primarily showing a tail portion and a head portion of the microelectromechanical probe respectively.

FIG. 37 is a lateral view of the microelectromechanical probe according to the seventh preferred embodiment of the present invention.

FIG. 38 is a schematic sectional view of a probe head according to an eighth preferred embodiment of the present invention.

### DETAILED DESCRIPTION OF THE INVENTION

First of all, it is to be mentioned that same reference numerals used in the following preferred embodiments and the appendix drawings designate same or similar elements throughout the specification for the purpose of concise illustration of the present invention. Besides, when it is mentioned that an element is disposed on another element, it means that the former element is directly disposed on the latter element, or the former element is indirectly disposed on the latter element through one or more other elements between aforesaid former and latter elements.

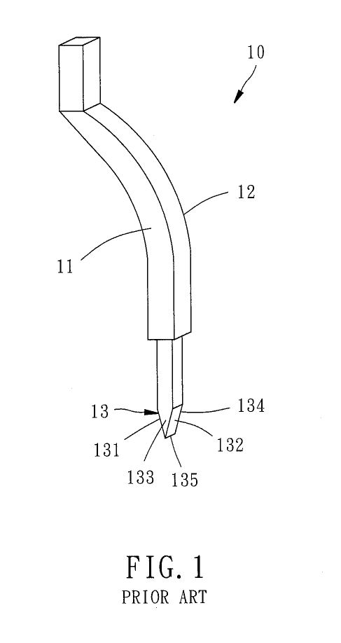

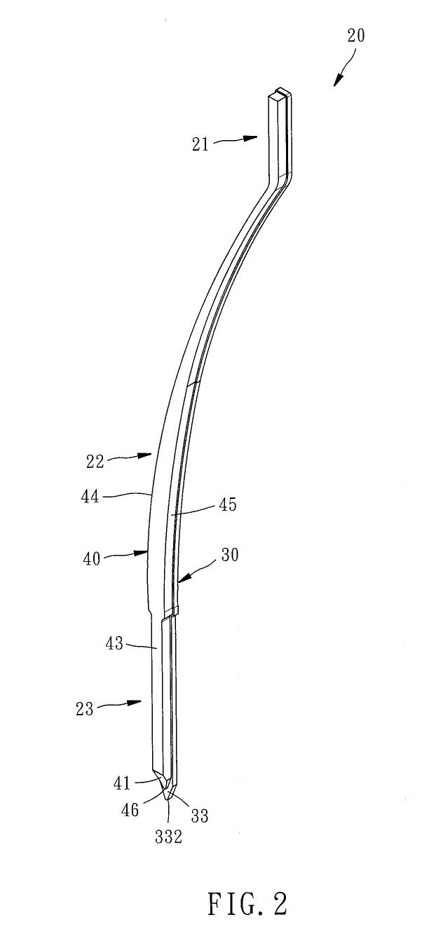

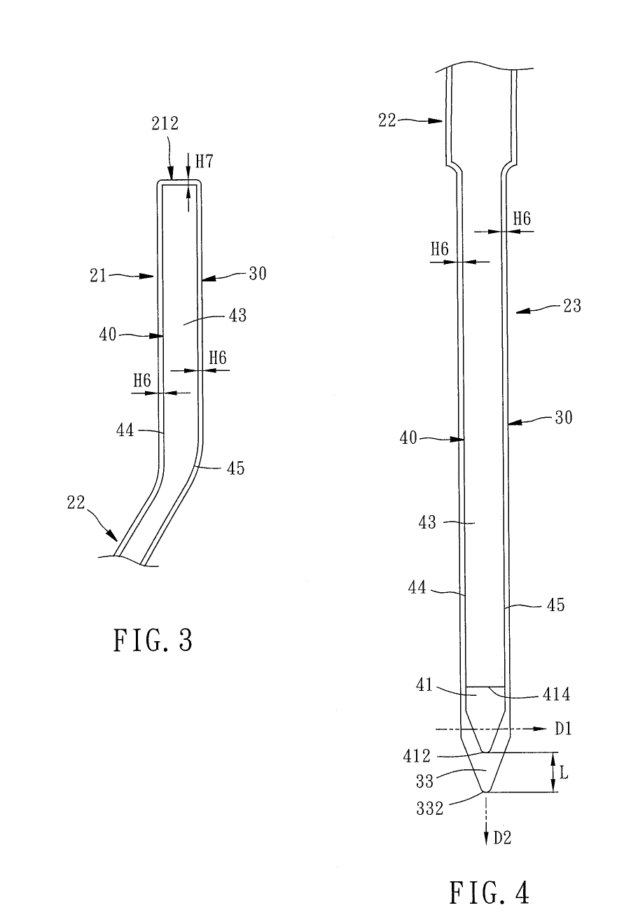

Referring to FIGS. 2-5, a microelectromechanical probe 20 according to a first preferred embodiment of the present invention is structurally compatible to the conventional buckling probe 10 made by the MEMS manufacturing process as shown in FIG. 1, but the microelectromechanical probe 20 in this embodiment includes a pinpoint layer 30 and a structural layer 40 made of different materials. The combination of the pinpoint layer 30 and the structural layer 40 forms a tail portion 21, a body portion 22 and a head portion 23 of the microelectromechanical probe 20. Besides, the microelectromechanical probe 20 in this embodiment and the conventional microelectromechanical probe have a difference in the configuration of the head portion therebetween. The method of manufacturing the microelectromechanical probe 20 will be described in the following paragraphs, and the structural features of the microelectromechanical probe 20 will be described at the same time. The method of manufacturing the microelectromechanical probe 20 includes the following steps.

a) As shown in FIG. 6, a pinpoint layer 30 is formed on a substrate 52 by a MEMS manufacturing process in a way that the pinpoint layer 30 has a bottom surface 31 facing the substrate 52 and a top surface 32 substantially opposite to the bottom surface 31.

The MEMS manufacturing process mentioned in the step a) includes the steps of forming a first sacrificial layer (not shown), which is made of metal or photoresist that can be easily removed, on the substrate 52 by photolithography technique, and then forming the pinpoint layer 30 in the first sacrificial layer by electroplating. These steps of the MEMS manufacturing process belong to conventional technology well known by person having ordinary skill in the art, and therefore will not be detailedly specified hereunder. As shown in FIG. 2, the shape of the pinpoint layer 30 is similar to the shape of the conventional buckling probe made by the MEMS manufacturing process, but the pinpoint layer 30 is provided with a smaller thickness.

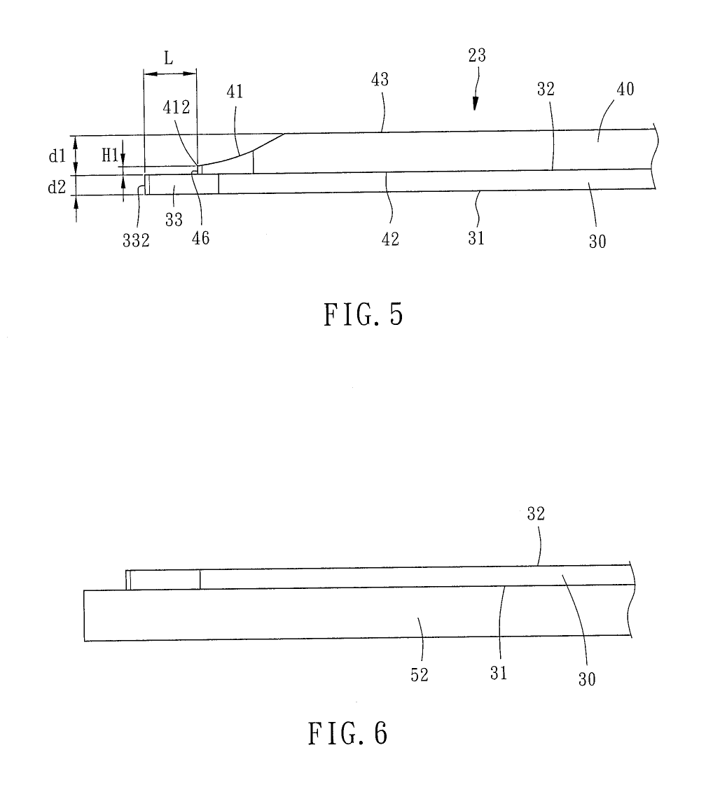

The top surface and the bottom surface mentioned in the present invention are named correspondingly to the state the probe is manufactured, i.e. the transversely lying state as shown in FIGS. 5-8, not the state the probe is in use, i.e. the vertical state as shown in FIG. 2.

b) Process the top surface 32 of the pinpoint layer 30 by planarization, such as mechanical grinding, chemical-mechanical polishing, and so on.

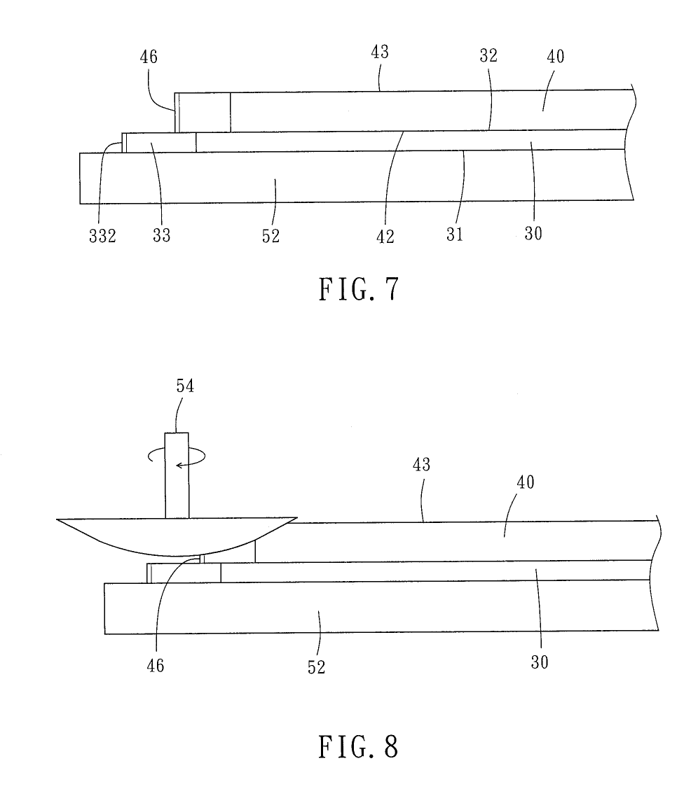

c) As shown in FIG. 7, a structural layer 40 is formed on the top surface 32 of the pinpoint layer 30 by another MEMS manufacturing process.

The MEMS manufacturing process mentioned in the step c) includes the steps of forming a second sacrificial layer (not shown) on the pinpoint layer 30 and the first sacrificial layer by photolithography technique, and then forming the structural layer 40 in the second sacrificial layer by electroplating. The pinpoint layer 30 and the structural layer 40 are made of different materials. For example, the material of the pinpoint layer 30 may be palladium (Pd), nickel (Ni), rhodium (Rh) or other alloys, and the material of the structural layer 40 may be gold (Au), copper (Cu), silver (Ag) or other alloys. The pinpoint layer 30 and the structural layer 40 are unlimited to be made of the aforesaid materials, as long as the pinpoint layer 30 has a hardness greater than the hardness of the structural layer 40, and the structural layer 40 has an electrical conductivity greater than the electrical conductivity of the pinpoint layer 30. At this step c), the structural layer 40 is similar to the pinpoint layer 30 in shape, but the outline of the structural layer 40 is a little smaller and located inside the outline of the pinpoint layer 30, and the thickness d1 of the structural layer 40 is greater than the thickness d2 of the pinpoint layer 30, as shown in FIG. 5.

Specifically speaking, when the step c) is accomplished, the structural layer 40 is approximately shaped as shown in FIG. 2, but not yet provided with a cutting face 41. At this state, the structural layer 40 has a bottom surface 42 combined with the top surface 32 of the pinpoint layer 30, a top surface 43 having the same shape with the bottom surface 42 and substantially facing in the same direction with the top surface 32, i.e. both top surfaces 43 and 32 face upward, a first side 44 and a second side 45 (as shown in FIG. 4) both adjoining the top surface 43, and a front terminal surface 46 (as shown in FIG. 7) adjoining the top surface 43 and the first and second sides 44 and 45. The pinpoint layer 30 has a pinpoint 33 protruding over the front terminal surface 46 of the structural layer 40 and located at the head portion 23. The length L of the pinpoint 33 (as shown in FIGS. 4-5) is preferably designed to be smaller than thirty micrometers, for preventing the pinpoint 33 from having too small thickness that is liable to cause fracture to the pinpoint.

d) As shown in FIG. 8, the structural layer 40 is cut from the first side 44 to the second side 45 by a cutting tool 54, so as to simultaneously provide the cutting face 41 as shown in FIGS. 2, 4 and 5 and reduce the area of the top surface 43 and the area of the front terminal surface 46 in a way that the cutting face 41 descends from the top surface 43 toward the pinpoint layer 30 to the front terminal surface 46, and the front terminal surface 46 is extended from a front end 412 of the cutting face 41, which is located nearest the top surface 32 within the cutting face 41, to the top surface 32, as shown in FIG. 5.

In other words, the microelectromechanical probe 20 of the present invention is initially formed by the MEMS manufacturing process, and then the cutting process is performed to remove a part of the initially formed structural layer 40 near the pinpoint 33, so as to simultaneously form the cutting face 41 and cut off a part of the initially formed top surface 43 and front terminal surface 46. After that, the front terminal surface 46 doesn't adjoin the top surface 43, but adjoins the cutting face 41.

After the step d) is accomplished, the first and second sacrificial layers (not shown) are removed so that the microelectromechanical probe 20 is separated from the substrate 52. The first and second sacrificial layers may be removed before the step d). However, in the condition that the first and second sacrificial layers are removed after the step d) is accomplished, the probe body composed of the pinpoint layer 30 and the structural layer 40 formed in the step a) to the step c) can be stably fixed on the substrate 52 by the first and second sacrificial layers while the step d) is performed, such that problems of displacement and deformation of the probe body, which may occur in the cutting process, can be prevented. Besides, in the process of forming the pinpoint layer 30 on the substrate 52 by the MEMS manufacturing process in the step a) as shown in FIG. 6, another sacrificial layer (not shown) may be provided between the substrate 52 and the pinpoint layer 30. In the aforesaid step of removing the sacrificial layers, the sacrificial layer located between the substrate 52 and the pinpoint layer 30 is also removed, so that the microelectromechanical probe 20 is separated from the substrate 52.

As a result, the pinpoint layer 30 can be made with a small thickness, which is accompanied with a small area of the probing end 332 of the pinpoint 33 for contacting the DUT, but the microelectromechanical probe 20 of the present invention still has high structural strength because of having not only the pinpoint layer 30 but also the structural layer 40. In this way, the microelectromechanical probe 20 makes small probing marks upon probing the DUT, easily pierces through the passivation layer of the DUT, and has high recognizability in the automatic pinpoint recognition process. Besides, the top surface 32 of the pinpoint layer 30 is processed by planarization, so the pinpoint layer 30 is not only uniform in thickness, but also prevented from burr edge produced on the probing end 332.

As shown in FIG. 5, the front terminal surface 46 is provided between the front end 412 of the cutting face 41 and the top surface 32 of the pinpoint layer 30, which means the front end 412 of the cutting face 41 doesn't directly adjoin the top surface 32 of the pinpoint layer 30, but a head distance H1 is reserved between the front end 412 of the cutting face 41 and the top surface 32 of the pinpoint layer 30 when the cutting face 41 is formed by the cutting process. In this way, the cutting process is conveniently performed and the pinpoint layer 30 is prevented from being damaged by the cutting process. Besides, this technical feature can increase the structural strength of the microelectromechanical probe 20 and extend electrical conductive effect without affecting the image recognition of the pinpoint. The perpendicular distance between the front end 412 of the cutting face 41 and the top surface 32 of the pinpoint layer 30, i.e. the length of the head distance H1, is preferably designed to be smaller than the thickness d2 of the pinpoint layer 30 or smaller than ten micrometers, such that the cutting process is still conveniently performed and prevented form affecting the image recognition of the pinpoint.

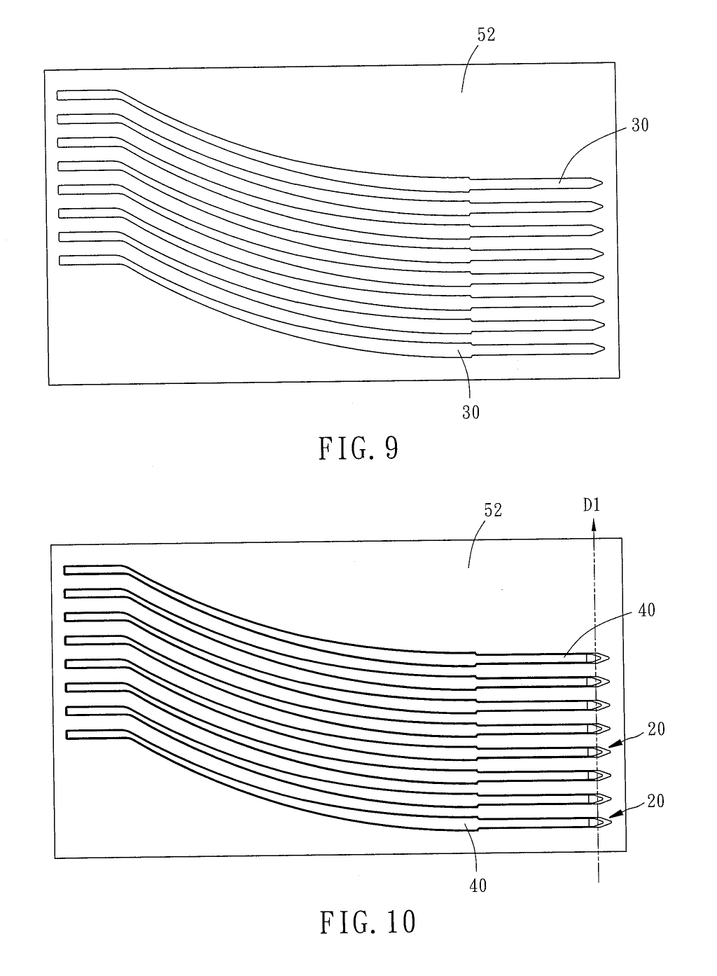

The aforesaid method can be performed to manufacture a plurality of microelectromechanical probes 20 on the same substrate 52 at the same time. That is, as shown in FIG. 9, a plurality of pinpoint layers 30 are manufactured on the substrate 52 in the MEMS manufacturing process in the step a); the top surfaces 32 of the pinpoint layers 30 are processed by planarization in the step b); a plurality of structural layers 40 are formed on the top surfaces 32 of the pinpoint layers 30 respectively in the MEMS manufacturing process in the step c); the structural layers 40 are cut in the aforesaid way in the same cutting process, as shown in FIG. 10. For the simplification of the figure and the convenience of illustration, an arrow is shown in FIG. 10 to represent the cutting direction D1, but the cutting tool 54 is not shown in FIG. 10. The aforesaid method is adapted for batch production of the microelectromechanical probe, which means a plurality of microelectromechanical probes 20 are manufactured at the same time. Besides, the top surfaces 32 of the pinpoint layers 30 of the microelectromechanical probes 20 are processed by planarization at the same time in the step b), so that the pinpoint layers 30 of the microelectromechanical probes 20 are equal in thickness. Therefore, when the microelectromechanical probes 20 are installed in the probe card to perform the testing work, they make uniform probing marks.

The cutting process mentioned in the present invention refers to any machining process which uses a cutting tool to contact a work piece directly and remove a part of the work piece, including milling, grinding, abrasive cutting and so on. The cutting tool may be a ball nose milling cutter, an abrasive wheel, a form grinding wheel, a single-tooth milling cutter, a multi-tooth milling cutter, and so on. In this way, the cutting face 41 has at least one cut mark formed by the cutting process, and the at least one cut mark is formed along the cutting direction D1, thereby substantially extended from the first side 44 to the second side 45.

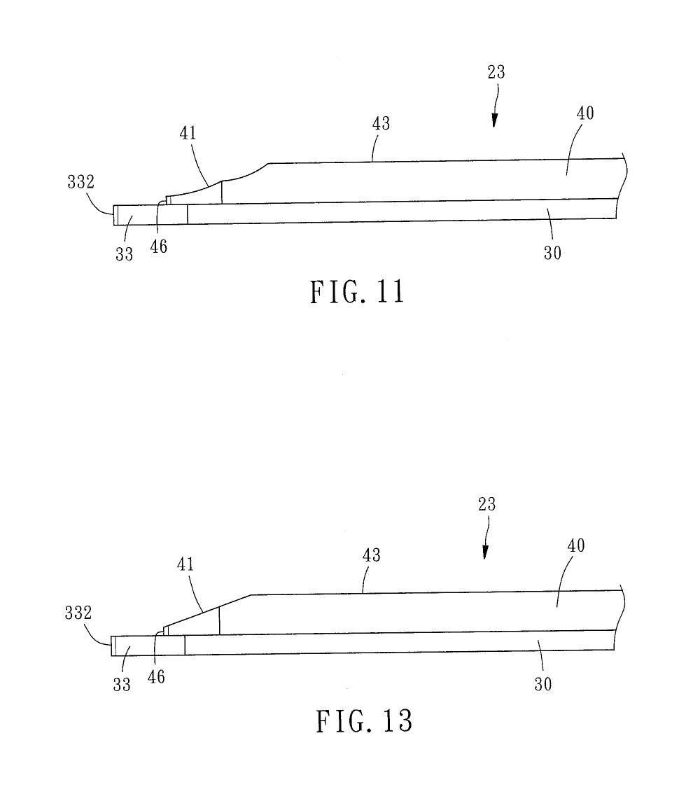

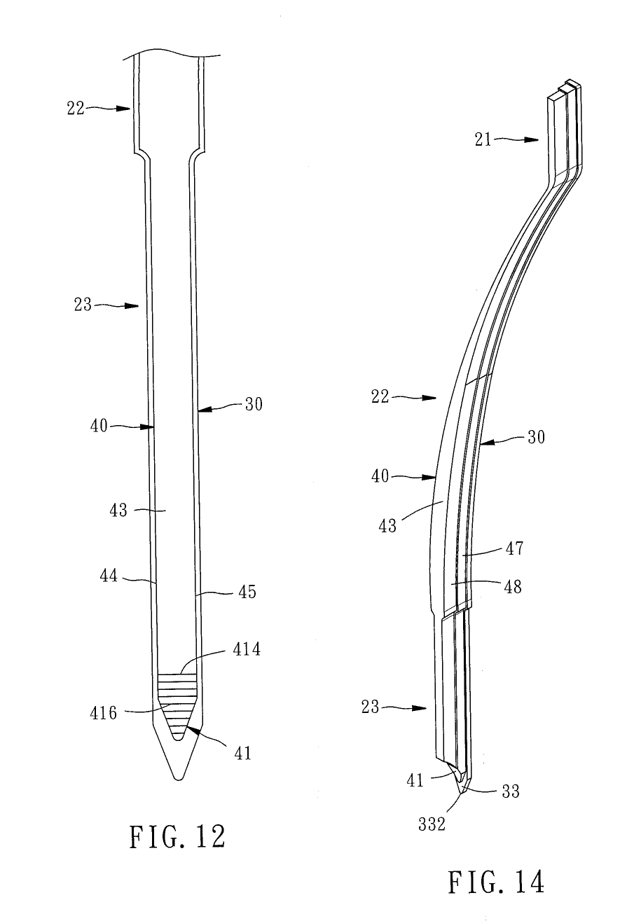

In the first preferred embodiment, the cutting tool 54 is a ball nose milling cutter, such that the obvious cut mark produced by which only includes an edge cut mark 414 located at an edge of the cutting face 41, as shown in FIG. 4. Besides, the cutting face 41 is formed by one-time processing, thereby shaped as a curved surface, as shown in FIG. 5. However, the cutting face 41 may be formed by multi-time processing to be shaped as a combination of multiple curved surfaces. For example, the cutting face 41 as shown in FIG. 11 is formed by two-time processing, thereby shaped as a combination of two curved surfaces. The cutting tool 54 may be an abrasive wheel, such that the cutting face 41 produced by which is also shaped as a curved surface, but has other cut marks 416 in addition to the edge cut mark 414. The cut marks 416 may be even provided all over the cutting face 41 regularly as shown in FIG. 12. The cutting face 41 may be shaped as a plane, as shown in FIG. 13. This means, the cutting face 41 may be a slope extended from the top surface 43 to the front terminal surface 46. Such cutting face 41 shaped as a plane may, but unlimited to, be formed by an abrasive wheel with single tapered side, a special single-tooth or multi-tooth milling cutter, or a ball nose milling cutter with relatively greater radius of curvature.

When the automatic pinpoint recognition process is performed subject to the microelectromechanical probe 20 of the present invention, the cut marks 414 and 416 of the cutting face 41 can scatter the light emitted to the cutting face 41, so the cutting face 41 is effective in light extinction, causing the light reflected by the probing end 332 of the pinpoint 33 relatively more obvious, thereby improving the image recognition of the pinpoint 33. The cut marks 414 and 416 of the cutting face 41 should be non-parallel to the probing direction D2, but unlimited to be perpendicular to the probing direction D2.

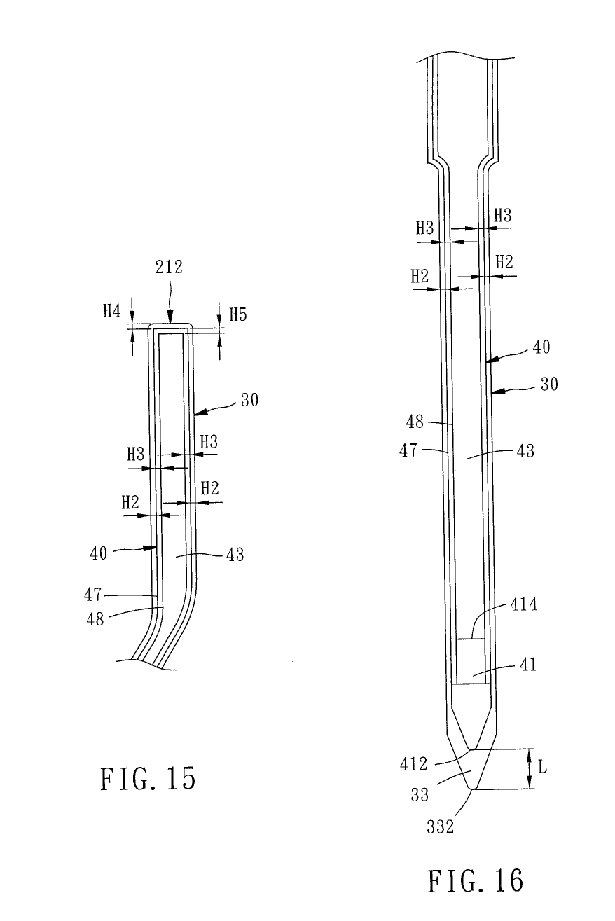

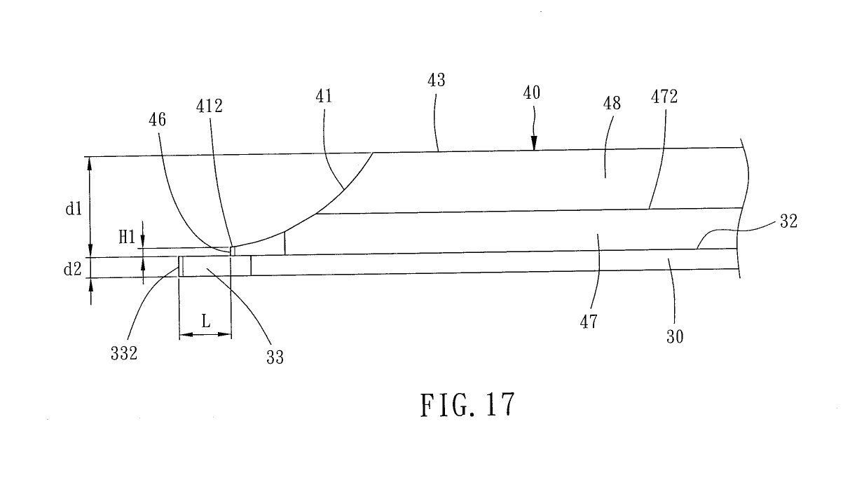

Referring to FIGS. 14-17, the microelectromechanical probe according to a second preferred embodiment of the present invention is different from the microelectromechanical probe according to the first preferred embodiment in that the structural layer 40 of the microelectromechanical probe of the second preferred embodiment includes a first layer 47 and a second layer 48 made of different materials. The first layer 47 is located between the pinpoint layer 30 and the second layer 48. That is, in the process of manufacturing the microelectromechanical probe of this embodiment by the aforesaid method, the step c) includes the steps of forming the first layer 47 on the top surface 32 of the pinpoint layer 30 and then forming the second layer 48 on a top surface 472 of the first layer 47 in a way that the first layer 47 and the second layer 48 are made of different materials. The first layer 47 may be a strengthening layer for increasing the structural strength of the probe, the second layer 48 may be an electrical conducting layer for increasing the electrical conductivity of the probe, and the material of the electrical conducting layer has an electrical conductivity greater than that of the material of the strengthening layer. Such arrangement is preferable for increasing the structural strength and electrical conductivity of the probe. However, the structural layer 40 may be arranged in a way that the first layer 47 is the electrical conducting layer and the second layer 48 is the strengthening layer. The aforesaid strengthening layer, which may be the first layer 47 or the second layer 48, may be made by a material same with the material of the pinpoint layer 30. For example, the material of the pinpoint layer 30 and the material of the strengthening layer may be both palladium (Pd), nickel (Ni), rhodium (Rh) or other alloys, and the material of the electrical conducting layer may be gold (Au), copper (Cu), silver (Ag) or other alloys. In such condition, one of the first layer 47 and the second layer 48, i.e. the strengthening layer, has hardness and electrical conductivity equal to that of the pinpoint layer 30, but the structural layer 40 still has the electrical conducting layer which is made by a material different from that of the pinpoint layer 30. Therefore, the whole structural layer 40 still fulfills the condition that the structural layer 40 has a hardness less than that of the pinpoint layer 30 and an electrical conductivity greater than that of the pinpoint layer 30. Alternatively, the first layer 47 and the second layer 48 may be both different from the pinpoint layer 30 in material. For example, the material of the pinpoint layer 30 and the material of the strengthening layer maybe two different materials of palladium (Pd), nickel (Ni), rhodium (Rh) and other alloys, and the material of the electrical conducting layer may be gold (Au), copper (Cu), silver (Ag) or other alloys.

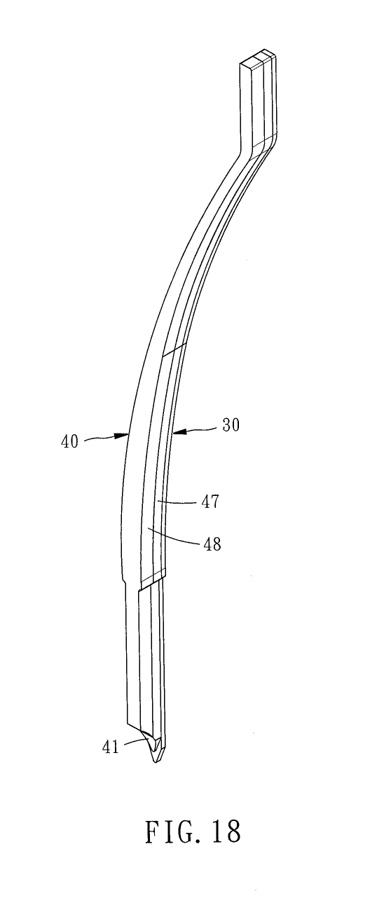

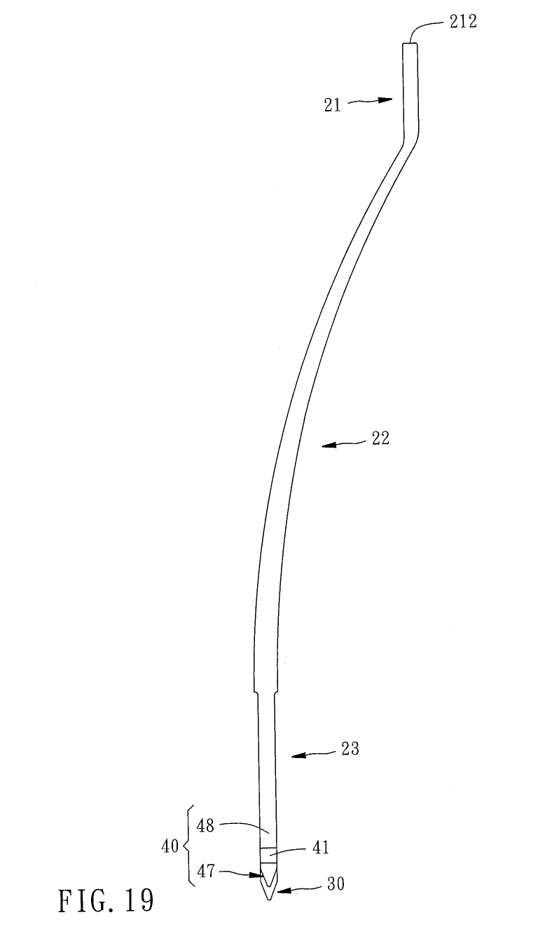

In the second preferred embodiment as shown in FIGS. 14-16, the outlines of the pinpoint layer 30, the first layer 47 and the second layer 48 are arranged in a terraced manner in order. Specifically speaking, the pinpoint layer 30 protrudes beyond the first side 44 and the second side 45 of the structural layer 40, and the first layer 47 of the structural layer 40 protrudes beyond the second layer 48 on the first side 44 and the second side 45. Therefore, there are two side distances H2 between the pinpoint layer 30 and the first layer 47 of the structural layer 40, and there are two side distances H3 between the first layer 47 and the second layer 48 of the structural layer 40. Besides, the pinpoint layer 30 protrudes beyond the structural layer 40 at the tail end 212 of the tail portion 21, and the first layer 47 of the structural layer 40 protrudes beyond the second layer 48 at the tail end 212 of the tail portion 21. Therefore, there is a tail distance H4 between the pinpoint layer 30 and the first layer 47 of the structural layer 40, and there is a tail distance H5 between the first layer 47 and the second layer 48 of the structural layer 40. Such configuration design not only makes the pinpoint layer 30, the first layer 47 and the second layer 48 be formed conveniently, but also increases the structural strength of the probe. However, the microelectromechanical probe of the present invention is unlimited to have the aforesaid side distance H2 or H3 or tail distance H4 or H5. For example, the microelectromechanical probe of the present invention may be shaped as the microelectromechanical probe according to a third preferred embodiment of the present invention as shown in FIGS. 18-19, wherein the pinpoint layer 30 and the first and second layers 47 and 48 of the structural layer 40 are flush with each other on two sides of the probe and the tail end of the tail portion, thereby having no such distances H2, H3, H4 and H5.

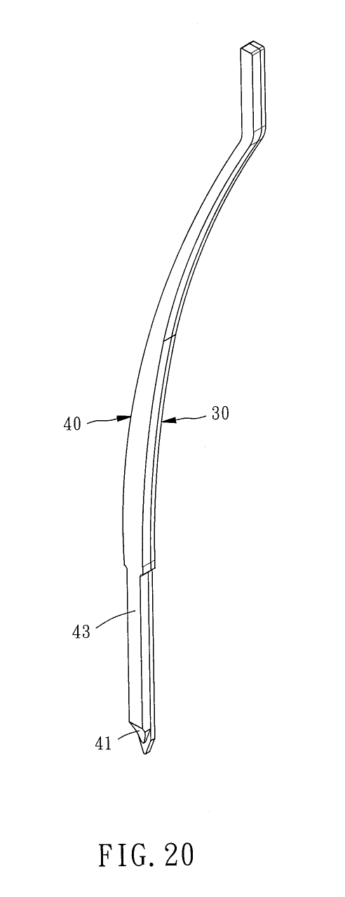

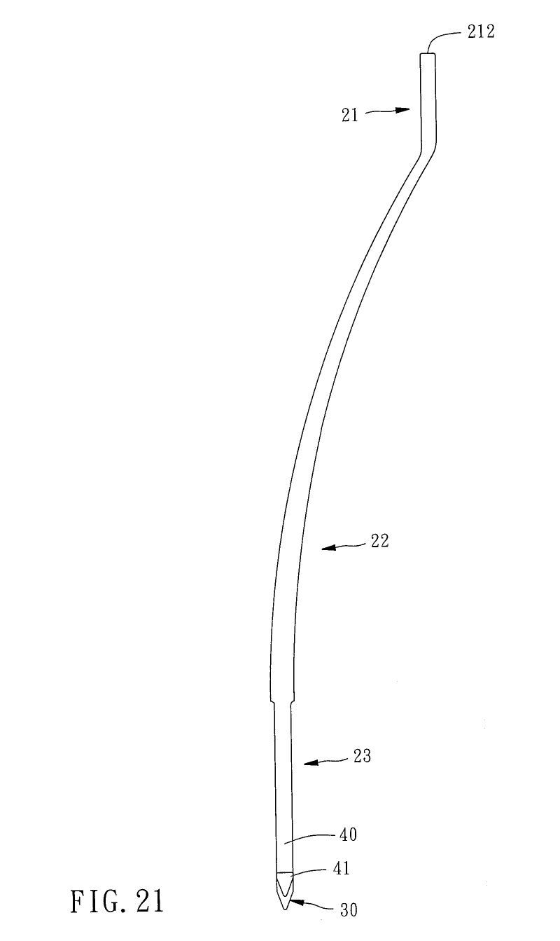

Likewise, in the first preferred embodiment as shown in FIGS. 2-4, the pinpoint layer 30 protrudes beyond the first side 44 and the second side 45 of the structural layer 40, and the pinpoint layer 30 protrudes beyond the structural layer 40 at the tail end 212 of the tail portion 21, so there are two side distances H6 and a tail distance H7 between the pinpoint layer 30 and the structural layer 40. Such configuration design not only makes the pinpoint layer 30 and the structural layer 40 be formed conveniently, but also increases the structural strength of the probe. However, the microelectromechanical probe of the present invention is unlimited to have the aforesaid side distance H6 or tail distance H7. For example, the microelectromechanical probe of the present invention may be shaped as the microelectromechanical probe according to a fourth preferred embodiment of the present invention as shown in FIGS. 20-21, wherein the pinpoint layer 30 and the structural layer 40 are flush with each other on two sides of the probe and the tail end of the tail portion, thereby having no such distances H6 and H7.

It is to be mentioned that the terraced structure on two sides of the probe may be provided only at the head portion 23 and the tail portion 21, but not at the body portion 22. That means the parts of the pinpoint layer 30, which are located within the head portion 23 and the tail portion 21, protrude beyond the first side 44 and the second side 45 of the structural layer 40. In the condition that the structural layer 40 includes the first layer 47 and the second layer 48, the part of the first layer 47, which is located within the head portion 23, protrudes beyond the part of the second layer 48, which is located within the head portion 23, on the first side 44 and the second side 45, and the part of the first layer 47, which is located within the tail portion 21, protrudes beyond the part of the second layer 48, which is located within the tail portion 21, on the first side 44 and the second side 45. In other words, the probe of the present invention may be provided with side distances at the head portion 23 and the tail portion 21, but without side distance at the body portion 22. The aforesaid configuration design is made due to the concern of hole matching because the head portion 23 and the tail portion 21 are adapted to be inserted through the installing holes of the dies of the probe seat (specified in the following paragraph). Therefore, when positioning the photoresist layers, the photomasks are provided in a terraced manner for the positioning. The body portion 22 doesn't need to be inserted in the installing hole of the dies, having no hole matching issue, so it can have no such terraced structure.

In the aforesaid embodiments, the head portion 23, the body portion 22 and the tail portion 21 of the structural layer 40 are formed integrally by a single material; alternatively, the first layer 47 of the structural layer 40, including the parts thereof within the head portion 23, the body portion 22 and the tail portion 21, is formed integrally by a single material, and then the second layer 48 of the structural layer 40, including the parts thereof within the head portion 23, the body portion 22 and the tail portion 21, is formed integrally by another single material. That means, the structural layer 40 in the aforesaid embodiments has a uniform structure at the head portion 23, the body portion 22 and the tail portion 21 thereof, which may be the single material structure or the dual material structure. However, the structural layer 40 of the microelectromechanical probe of the present invention is unlimited to have the uniform single material structure or dual material structure at the head portion 23, the body portion 22 and the tail portion 21 thereof. For example, the structural layer 40 may have the tail portion 21 thereof be made by a material same as the material of the pinpoint layer 30, but have the head portion 23 and the body portion 22 be made of a material different from the material of the pinpoint layer 30. Alternatively, the material of the part of the structural layer 40 within the body portion 22 may have an electrical conductivity greater than that of the material of the part of the structural layer 40 within the head portion 23 and/or the tail portion 21, for preventing the narrowest part of the body portion 22 from being damaged by overheat when conducting electricity. The arrangement of the material of the structural layer 40 can be modified, as long as within the head portion 23 of the microelectromechanical probe, the pinpoint layer 30 has a hardness greater than that of the structural layer 40, and the structural layer 40 has an electrical conductivity greater than the pinpoint layer 30. The structural layer 40 may be even provided only at the head portion 23 and the body portion 22 but not at the tail portion 21, and the tail portion 21 may be strengthened by another structure.

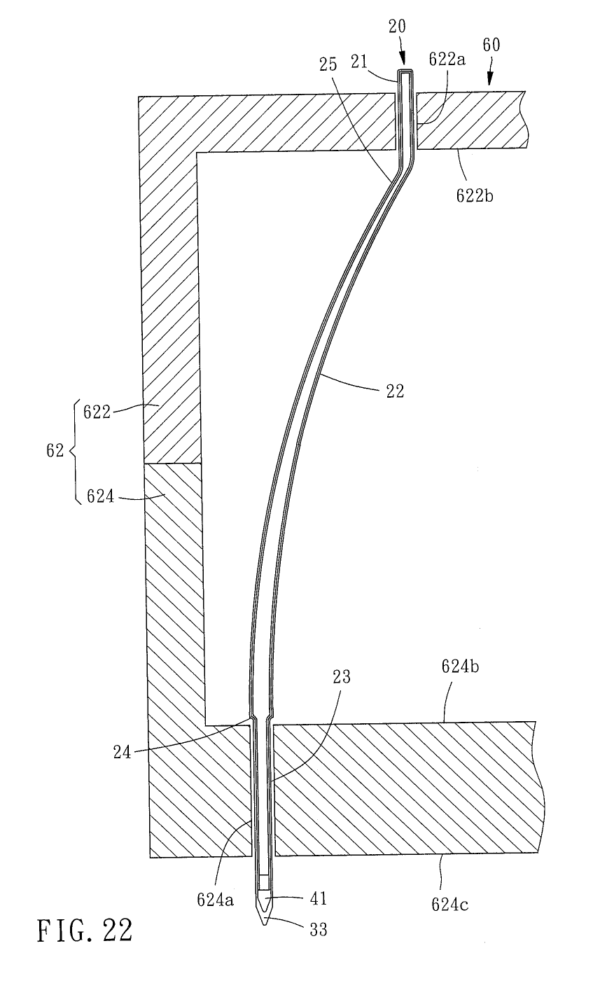

The aforesaid microelectromechanical probe of the present invention is adapted to be installed in a probe seat to compose a probe head, such as the probe head 60 according to a fifth preferred embodiment of the present invention as shown in FIG. 22. The probe seat 62 of the probe head 60 includes an upper die 622 and a lower die 624. The upper and lower dies 622 and 624 may be directly connected with each other. Alternatively, the probe seat 62 may further include a middle die (not shown) disposed between the upper and lower dies 622 and 624, depending on demands. The upper and lower dies 622 and 624 are provided with a plurality of installing holes 622a and 624a respectively, for the installation of a plurality of microelectromechanical probes 20. For the simplification of the figure and the convenience of illustration, there are only one installing hole 622a of the upper die 622, one installing hole 624a of the lower die 624 and one microelectromechanical probe 20 shown in FIG. 22. The microelectromechanical probe 20 may be anyone provided in the aforesaid embodiments. For example, the microelectromechanical probe 20 of the second preferred embodiment is adopted in this embodiment. The tail portion 21 and the head portion 23 of the microelectromechanical probe 20 are inserted through the installing holes 622a and 624a of the upper and lower dies 622 and 624 respectively. A lower stopping portion 24 is provided between the head portion 23 and the body portion 22 for being stopped by a stopping surface 624b of the lower die 624, thereby preventing the microelectromechanical probe 20 from escaping from the probe seat 62. Besides, an upper stopping portion 25 is provided between the tail portion 21 and the body portion 22 for being stopped by a stopping surface 622b of the upper die 622, thereby preventing the microelectromechanical probe 20 from escaping from the probe seat 62.

The upper die 622 may be fixed to a main circuit board of a probe card (not shown), so that the tail portion 21 of the microelectromechanical probe 20 is electrically connected with the main circuit board directly. Alternatively, the upper die 622 may be fixed to a space transformer of a probe card (not shown), and the space transformer is fixed to a main circuit board of the probe card (not shown), so that the tail portion 21 of the microelectromechanical probe 20 is electrically connected with the main circuit board indirectly through the space transformer. The pinpoint 33 and the cutting face 41 of the microelectromechanical probe 20 are both completely exposed out of the lower die 624, i.e. located under the bottom surface 624c of the lower die 624. Therefore, the probing end 332 of the pinpoint 33 can be used to probe the electrical conductive pad of the DUT (not shown), causing the electrical conductive pad of the DUT to be electrically connected with the main circuit board through the microelectromechanical probe 20, so that the DUT and a test equipment (not shown) can transmit test signals to each other through the main circuit board.

In the process that the probe head 60 is assembled, when the microelectromechanical probe 20 of the present invention is inserted into the installing holes 622a and 624a of the dies 622 and 624 of the probe seat 62, the cutting face 41 can perform a guiding function to make the head portion 23 be easily inserted through the installing holes 622a and 624a, thereby preventing the microelectromechanical probe 20 from the collision with the dies 622 and 624. In other words, the cutting face 41 is effective in not only light extinction but also improving the convenience of the probe installation.

In conclusion, the primary technical features of the microelectromechanical probe of the present invention lies in that the microelectromechanical probe 20 is composed of the pinpoint layer 30 with relatively greater hardness and the structural layer 40 with relatively greater electrical conductivity; the top surface 32 of the pinpoint layer 30 is processed by planarization; the pinpoint 33 for probing the DUT is formed by only the pinpoint layer 30; the structural layer 40 is provided near the pinpoint 33 with the cutting face 41 and the front terminal surface 46. The aforesaid technical features are unlimited to be applied to the buckling probe as provided in the aforesaid embodiments, but applicable to the microelectromechanical probe with other shapes, such as the straight probe, the N-shaped probe, and so on.

It is to be mentioned that the head portion 23 mentioned in the present invention refers to the parts of the probe inserted in the installing hole 624a of the lower die 624 and located under the lower die 624; the tail portion 21 refers to the parts of the probe inserted in the installing hole 622a of the upper die 622 and located above the upper die 622. As to the buckling probe provided in the aforesaid embodiments, the head portion 23 refers to the part under the lower stopping portion 24, and the tail portion 21 refers to the part above the upper stopping portion 25. However, as to the straight probe, such as that will be described in the following sixth to eighth preferred embodiments, when it is not yet installed in the probe seat, it has no buckling structure, thereby unable to be obviously divided into tail, body and head portions. When the straight probe is inserted through the upper and lower dies, the upper and lower dies can be displaced in opposite directions to cause the straight probe have buckling structure and thereby divide the straight probe into tail, body and head portions.

The aforesaid front terminal surface having the head distance H1 may still reflect some light and thereby a little influence the image recognition of the pinpoint. Besides, if the head distance H1 is cut off by the aforesaid cutting tool in the aforesaid cutting process, the pinpoint layer 30 is liable to be partially cut off as well. That will provide a concave on the exposed part of the top surface 32 of the pinpoint layer 30. The probe in use is liable to have stress concentration at the concave, thereby fractured. For avoiding the aforesaid problem, the present invention further provides another microelectromechanical probe, the manufacturing method thereof, and the probe head having the microelectromechanical probe in the following sixth to eighth preferred embodiments of the present invention.

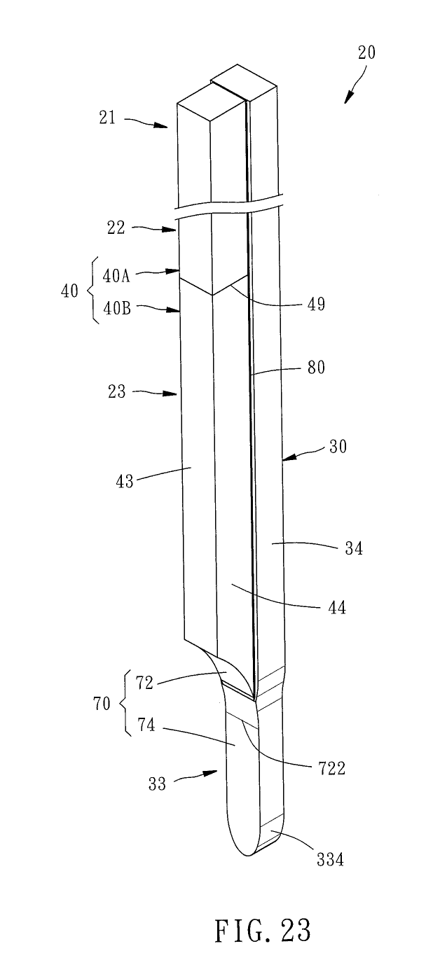

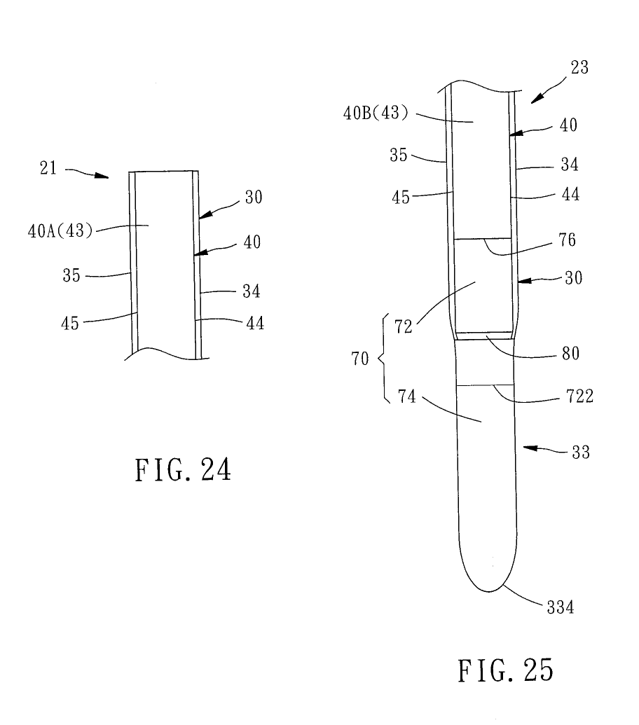

Referring to FIGS. 23-26, the microelectromechanical probe 20 according to the sixth preferred embodiment of the present invention is structurally compatible with the conventional microelectromechanical probe made by the MEMS manufacturing process as shown in FIG. 1, but the microelectromechanical probe 20 in this embodiment is straight-shaped before it is inserted in the probe head. Of course, the microelectromechanical probe 20 can be shaped as the buckling probe as shown in FIG. 1. The microelectromechanical probe 20 in this embodiment includes a pinpoint layer 30, a structural layer 40, a cutting face 70, and an attachment layer 80. The combination of the pinpoint layer 30, the structural layer 40 and the attachment layer 80 forms a tail portion 21, a body portion 22 and a head portion 23 of the microelectromechanical probe 20. The cutting face 70 is located at the head portion 23 and defines a pinpoint 33. That means in this embodiment the length of the pinpoint 33 equals to the length of the cutting face 70. Besides, the microelectromechanical probe 20 in this embodiment and the conventional microelectromechanical probe have a difference in the configuration of the head portion therebetween. The method of manufacturing the microelectromechanical probe 20 of this embodiment will be described in the following paragraphs, and the structural features of the microelectromechanical probe 20 will be described at the same time. The method of manufacturing the microelectromechanical probe 20 includes the following steps.

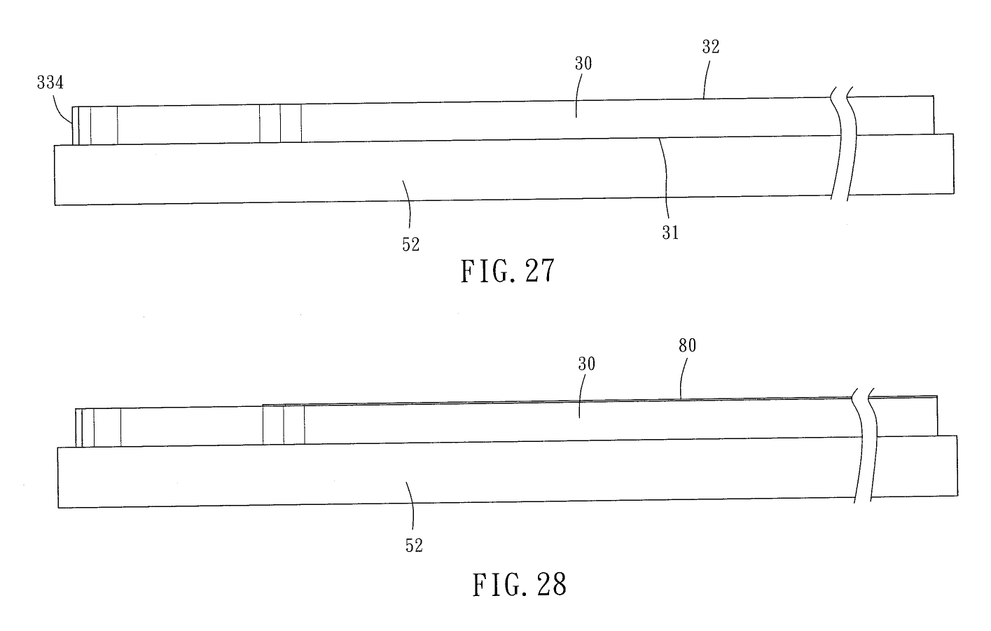

a) As shown in FIG. 27, a pinpoint layer 30 is formed on a substrate 52 by a MEMS manufacturing process in a way that the pinpoint layer 30 has a bottom surface 31 facing the substrate 52, a top surface 32 substantially opposite to the bottom surface 31, a first side 34 and a second side 35 (as shown in FIGS. 23-25) both adjoining the top surface 32 and the bottom surface 31, and a probing end surface 334 adjoining the top surface 32, the bottom surface 31, the first side 34 and the second side 35 and located at the head portion 23.

The MEMS manufacturing process mentioned in the step a) includes the steps of forming a first sacrificial layer (not shown), which is made of metal or photoresist that can be easily removed, on the substrate 52 by photolithography technique, and then forming the pinpoint layer 30 in the first sacrificial layer by electroplating. These steps of the MEMS manufacturing process belong to conventional technology well known by person having ordinary skill in the art, and therefore will not be detailedly specified hereunder. As shown in FIG. 23, the shape of the pinpoint layer 30 is similar to the shape of the conventional straight probe made by the MEMS manufacturing process, but the pinpoint layer 30 is provided with a smaller thickness, and the probing end surface 334 is archedly extended from the first side 34 of the pinpoint layer 30 to the second side 35 of the pinpoint layer 30, which means the whole probing end surface 334 is arc-shaped. However, in this embodiment the probing end surface 334 of the microelectromechanical probe 20 is unlimited to the aforesaid shape. For example, the probing end surface 334 may be cone-shaped as shown in FIG. 1, plane-shaped, and so on.

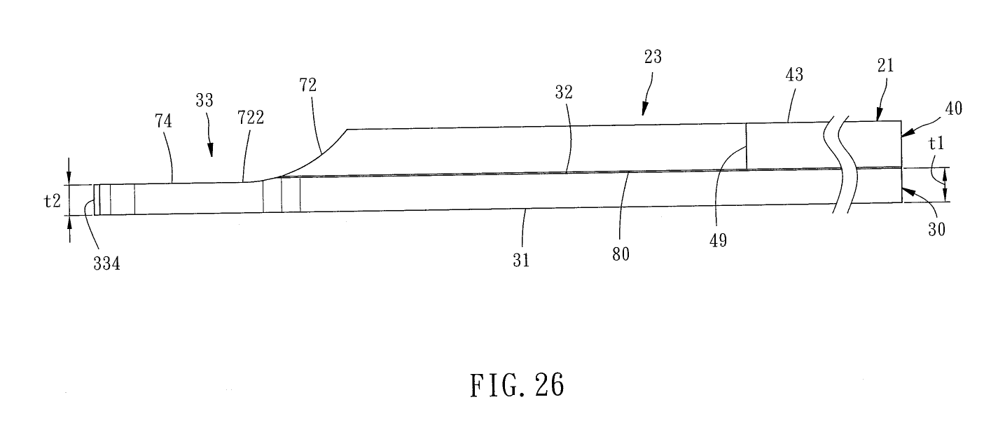

As mentioned above, the top surface and the bottom surface mentioned in the present invention are named correspondingly to the state the probe is manufactured, i.e. the transversely lying state as shown in FIGS. 26-31, not the state the probe is in use, i.e. the vertical state as shown in FIG. 23.

b) Process the top surface 32 of the pinpoint layer 30 by planarization, such as mechanical grinding, chemical-mechanical polishing, and so on.

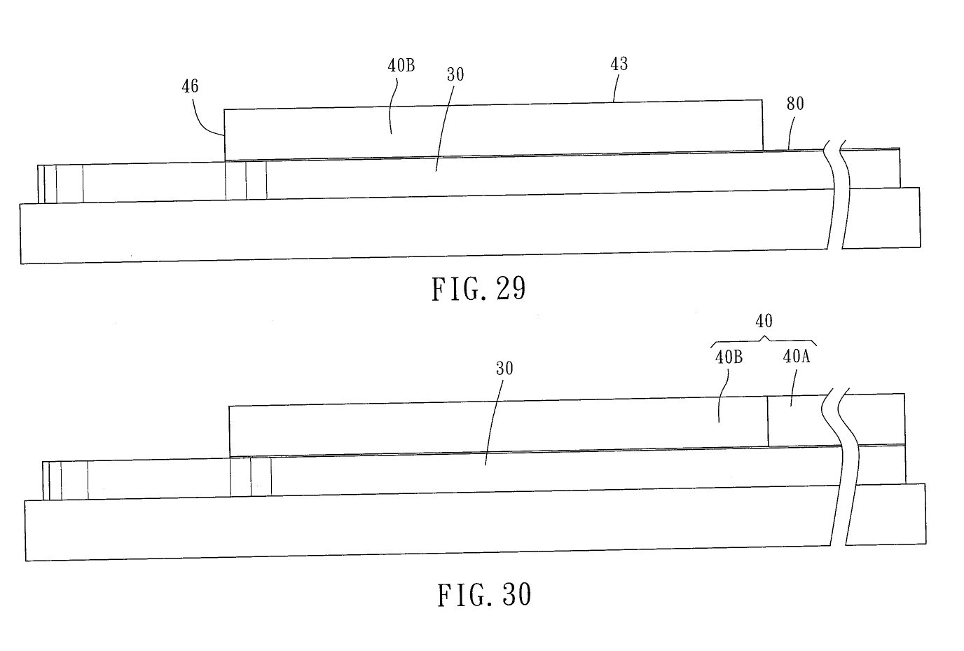

c) As shown in FIGS. 28-30, a structural layer 40 is formed on the top surface 32 of the pinpoint layer 30 by another MEMS manufacturing process in a way that the structural layer 40 has a top surface 43 substantially facing in the same direction with the top surface 32, and a first side 44, a second side 45 (as shown in FIGS. 23-25) and a front terminal surface 46 (as shown in FIG. 29) all adjoining the top surface 43; the first side 44 of the structural layer 40 and the first side 34 of the pinpoint layer 30 substantially face a same direction, and the second side 45 of the structural layer 40 and the second side 35 of the pinpoint layer 30 substantially face a same direction; the structural layer 40 has an electrical conductivity greater than that of the pinpoint layer 30.

In this embodiment, the structural layer 40 includes a first section 40A and a second section 40B made of different materials. The first section 40A is extended from the tail portion 21 toward the head portion 23 and provided with a connecting end 49. The second section 40B is extended from the connecting end 49 toward the probing end surface 334 to the pinpoint 33. An attachment layer 80 may be optionally provided between the structural layer 40 and the pinpoint layer 30. The first section 40A and the second section 40B of the structural layer 40 are both indirectly fixed on the top surface 32 of the pinpoint layer 30 through the attachment layer 80 if the attachment layer 80 is provided therebetween.

Therefore, in this embodiment the MEMS manufacturing process mentioned in the step c) includes the steps of forming a second sacrificial layer (not shown) on the pinpoint layer 30 and the first sacrificial layer by photolithography technique, then forming the attachment layer 80 in the second sacrificial layer by electroplating as shown in FIG. 28, then forming a third sacrificial layer (not shown) on the attachment layer 80 and the second sacrificial layer by photolithography technique, then forming the second section 40B in the third sacrificial layer by electroplating as shown in FIG. 29, then removing the third sacrificial layer, then forming a fourth sacrificial layer (not shown) on the attachment layer 80 and the second sacrificial layer by photolithography technique, and then forming the first section 40A in the fourth sacrificial layer by electroplating as shown in FIG. 30.

The first section 40A of the structural layer 40 may be formed before the second section 40B. The structural layer 40 may be made of a single material without being divided into the first and second sections. There may be no attachment layer 80 provided between the structural layer 40 and the pinpoint layer 30. In the aforesaid three conditions, the detail of the step c) is a little different from the above description, which can be easily understood by reference to the precedent embodiments, and therefore will not be detailedly specified hereunder.

In this embodiment, the second section 40B of the structural layer 40 and the pinpoint layer 30 are made of the same material which has a relatively higher hardness, such as cobalt-palladium alloy, rhodium (Rh), and so on. The material of the first section 40A of the structural layer 40 is made by a material having relatively higher electrical conductivity, such as copper (Cu), and so on. Because the material of the pinpoint layer 30 and the second section 40B of the structural layer 40 is inert material, which may be unable to be perfectly combined with the same material, the attachment layer 80 is made of the material capable of combining the pinpoint layer 30 and the second section 40B of the structural layer 40 well, such as the material same with that of the first section 40A. However, the pinpoint layer 30, the first and second sections 40A and 40B of the structural layer 40, and the attachment layer 80 are unlimited to be made of the aforesaid materials, as long as the whole structural layer 40 is higher in electrical conductivity than the pinpoint layer 30. Although in this embodiment the second section 40B of the structural layer 40 and the pinpoint layer 30 are made by a same material having identical electrical conductivity, the electrical conductivity of the whole structural layer 40 is still higher than the electrical conductivity of the pinpoint layer 30 because the first section 40A is made by a material having relatively higher electrical conductivity than the material of the pinpoint layer 30.

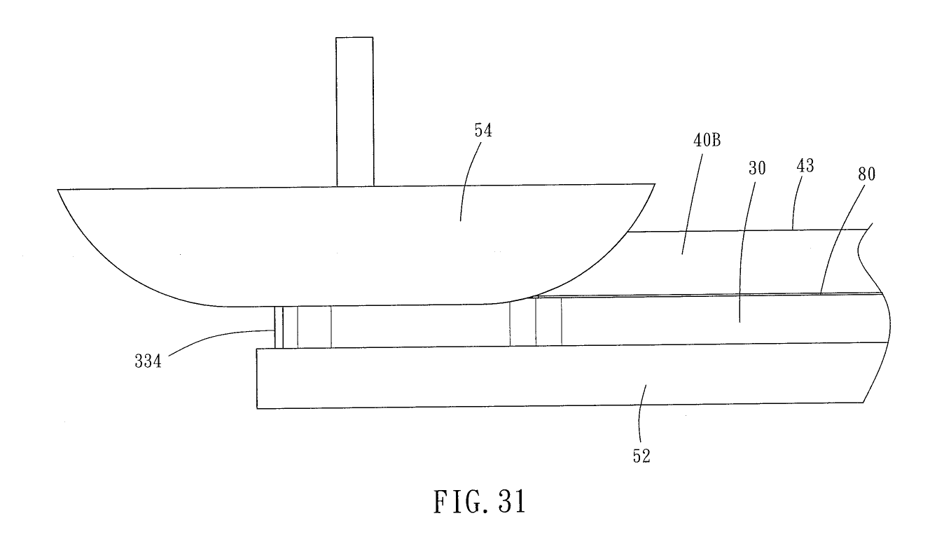

d) As shown in FIG. 31, the pinpoint layer 30 and the structural layer 40 is cut from the first side 34 of the pinpoint layer 30 and the first side 44 of the structural layer 40 to the second side 35 of the pinpoint layer 30 and the second side 45 of the structural layer 40 by a bull nose end mill 54, so as to simultaneously provide a cutting face 70, cut off the front terminal surface 46 of the structural layer 40 and reduce the area of the top surface 43 and the area of the probing end surface 334 in a way that the cutting face 70 has a curved section 72 curvedly descending from the top surface 43 of the structural layer 40 to the pinpoint layer 30 and having a bottom end 722 located at the pinpoint layer 30, and a flat section 74 extended from the bottom end 722 of the curved section 72 substantially parallel to the top surface 32 or the bottom surface 31 to the probing end surface 334, as shown in FIG. 26. The pinpoint layer 30 has a first thickness t1 defined by the bottom surface 31 and the top surface 32 of the pinpoint layer 30, and a second thickness t2 defined by the bottom surface 31 and the flat section 74 of the cutting face 70. The first thickness t1 is greater than the second thickness t2.

In other words, the microelectromechanical probe 20 in this embodiment is initially formed by the MEMS manufacturing process, and then the cutting process is performed to remove a part of the initially formed structural layer 40 and a part of the initially formed pinpoint layer 30, so as to simultaneously form the cutting face 70 and cut off the whole initially formed front terminal surface 46 of the structural layer 40, a part of the initially formed top surface 43 and a part of the initially formed probing end surface 334. After that, the probing end surface 334 doesn't adjoin the top surface 32, but adjoins the flat section 74 of the cutting face 70.

After the step d) is accomplished, the sacrificial layers (not shown) are removed so that the microelectromechanical probe 20 is separated from the substrate 52. The effect of the sacrificial layers is the same as that of the first and second sacrificial layers mentioned in the first preferred embodiment, and the sacrificial layers may be removed before the step d).

As a result, the microelectromechanical probe in this embodiment also has the effect of the microelectromechanical probe mentioned in the first preferred embodiment. Furthermore, because the pinpoint layer 30 can be made with a small thickness and the probing end surface 334 is located at the relatively thinner section of the pinpoint layer 30 resulted from the cutting process, i.e. the section having the flat section 74 of the cutting face 70, the microelectromechanical probe 20 of this embodiment makes smaller probing marks upon probing the DUT and more easily pierces through the passivation layer of the DUT than the microelectromechanical probe 20 of the first embodiment. Besides, the cutting face 70 is extended from the top surface 43 of the structural layer 40 to the probing end surface 334. Therefore, except for the probing end surface 334, the other surface of the probe 20 facing the light for the pinpoint recognition process, i.e. the surface facing the left in FIG. 26, is formed by the cutting process and thereby effective in light extinction, so that the recognizability of the pinpoint is relatively higher than the precedent embodiments. In addition, the curved section 72 and the flat section 74 of the cutting face 70 can be simultaneously formed in the cutting process using the bull nose end mill 54, so the manufacturing process of the microelectromechanical probe 20 is relatively faster because the cutting process is simple. Besides, the part of the pinpoint 33, which has the flat section 74, is uniform in thickness and therefore has no undulation or concave. As a result, although the pinpoint 33 of the microelectromechanical probe 20 is very thin because of the cutting process, the thinnest part thereof, i.e. the part having the flat section 74, is flat-shaped and thereby prevented from stress concentration, so that the probe is not easily fractured.

As mentioned above, in this embodiment the whole probing end surface 334 is arc-shaped. In this way, when the probing end surface 334 of the microelectromechanical probe 20 is worn because of probing the DUT or being cleaned, the area of the probing end, i.e. the area of the part of the probing end surface 334 contacting the DUT, is relatively less increased due to the wearing of the probing end surface 334, so the probing marks are relatively less widened.

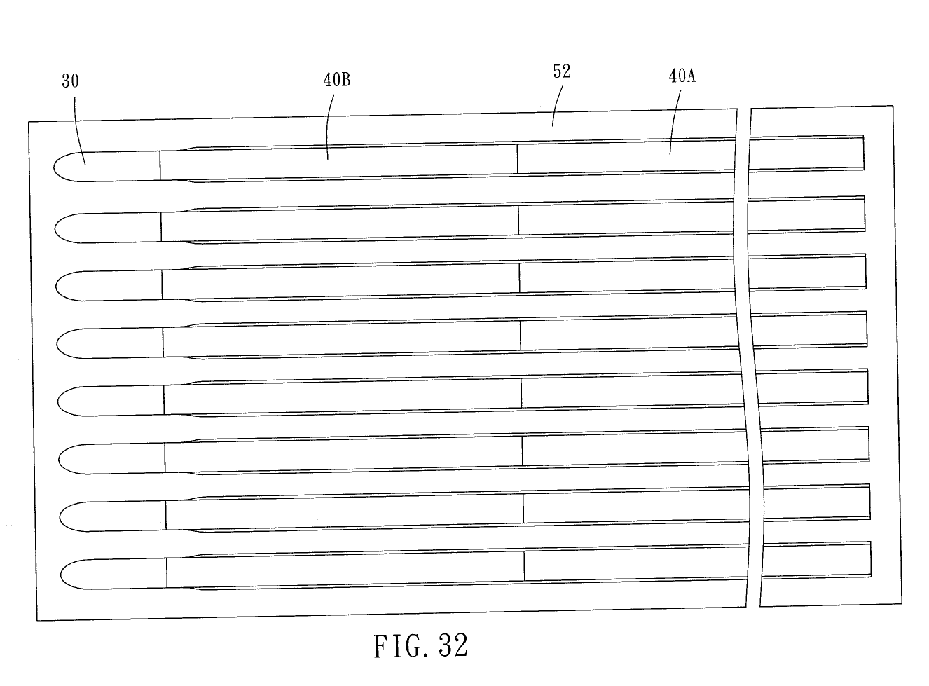

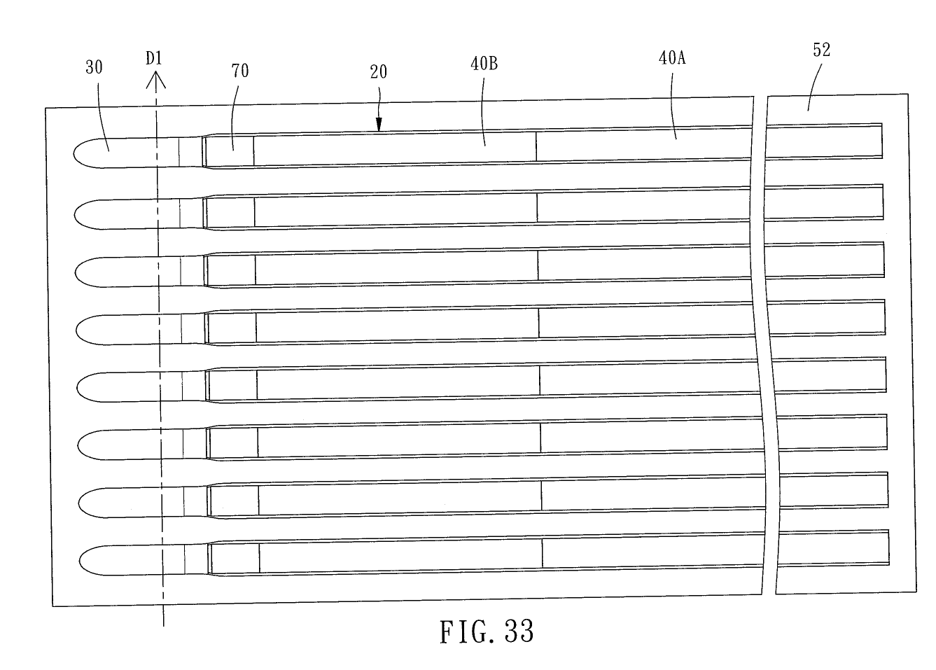

The manufacturing method in this embodiment can be performed to manufacture a plurality of microelectromechanical probes 20 on the same substrate 52 at the same time, as shown in FIGS. 32-33. The steps and the effect of the method are similar to that mentioned in the first preferred embodiment, therefore not to be repeatedly mentioned hereunder.

Because of the cutting process, the cutting face 70 has at least one cut mark formed along the cutting direction D1. The cut mark is substantially extended from the first side 34 of the pinpoint layer 30 or the first side 44 of the structural layer 40 to the second side 35 of the pinpoint layer 30 or the second side 45 of the structural layer 40. As shown in FIG. 25, the cutting face 70 in this embodiment has only one obvious cut mark 76 located at the edge of the cutting face 70 adjoining the top surface 43. Actually, there are unobvious cut marks uniformly provided all over the cutting face 70. These cut marks can scatter the light emitted to the cutting face 70, thereby being effective in light extinction. Therefore, during the automatic pinpoint recognition process performed to the microelectromechanical probes 20 of the present invention, only the probing end surface 334 of the pinpoint 33 reflects light obviously, so that the recognizability of the pinpoint 33 is relatively higher.

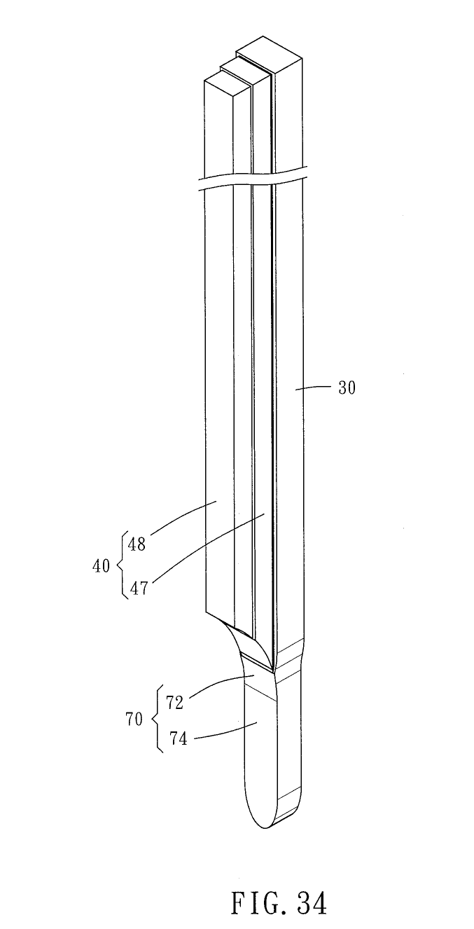

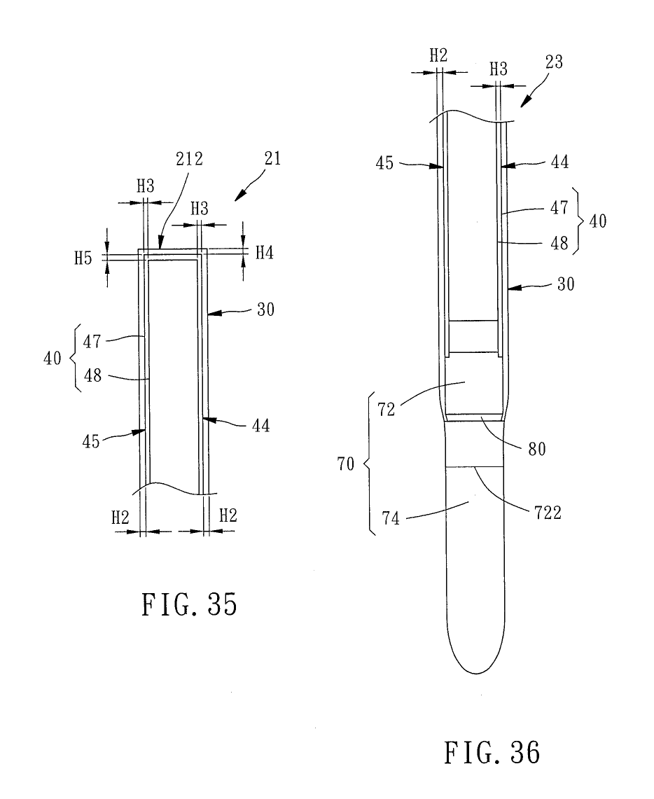

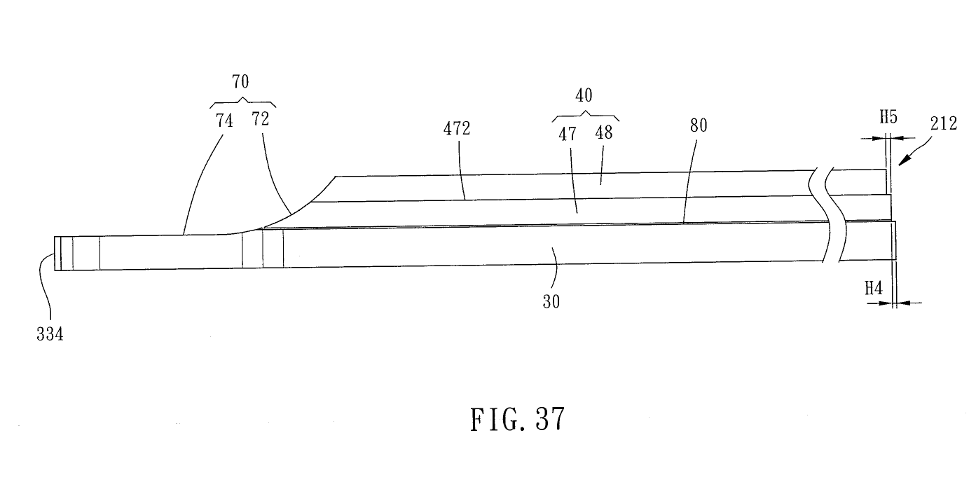

Referring to FIGS. 34-37, the microelectromechanical probe according to the seventh preferred embodiment of the present invention is different from the microelectromechanical probe according to the sixth preferred embodiment in that the structural layer 40 of the microelectromechanical probe of the seventh preferred embodiment includes a first layer 47 and a second layer 48 made of different materials, and the outlines of the pinpoint layer 30, the first layer 47 and the second layer 48 are arranged in a terraced manner in order. Such configuration design is similar to that mentioned in the aforesaid second preferred embodiment, therefore not to be repeatedly mentioned hereunder.

As mentioned above, in the condition that the structural layer 40 is not divided into the first and second layers, the pinpoint layer 30 may protrude beyond the first side 44 and the second side 45 of the structural layer 40, and the pinpoint layer 30 may protrude beyond the structural layer 40 at the tail end 212 of the tail portion 21. Likewise, the microelectromechanical probe of this embodiment is unlimited to have the aforesaid terraced structure. Alternatively, the terraced structure on two sides of the probe may be provided only at the head portion 23 and the tail portion 21, but not at the body portion 22.

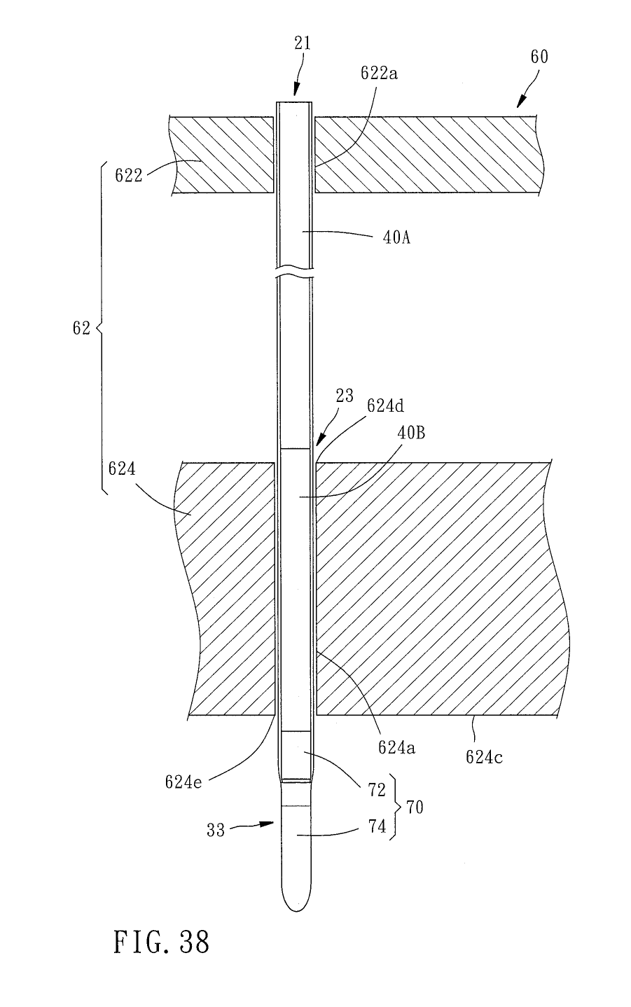

Referring to FIG. 38, the probe head 60 according to the eighth preferred embodiment of the present invention is different from the probe head according to the aforesaid fifth preferred embodiment in that the probe head 60 in the eighth preferred embodiment uses the microelectromechanical probe provided in the sixth preferred embodiment. The tail portion 21 and the head portion 23 of the microelectromechanical probe 20 are inserted through the installing holes 622a and 624a of the upper and lower dies 622 and 624 respectively. After that, the upper and lower dies 622 and 624 can be displaced in opposite directions to make the straight microelectromechanical probe 20 have buckling structure, such that the probe 20 can be maintained in the upper and lower dies 622 and 624 and prevented from falling. The microelectromechanical probe in the probe head of this embodiment also has the probing function and the effect of improving the convenience of the probe installation as mentioned in the fifth preferred embodiment. It is to be mentioned that the probe head is unlimited to have only one upper die 622 or lower die 624. Specifically speaking, the probe head may have one or more upper dies 622 and one or more lower dies 624, for facilitating installation of the aforesaid microelectromechanical probes of the present invention therein.

In addition, the structural layer 40 of the microelectromechanical probe 20 in this embodiment has the aforesaid first and second sections 40A and 40B, so that the part of the structural layer 40 located in the installing hole 624a of the lower die 624 can be made of a material with relatively higher hardness, i.e. the material of the second section 40B. Besides, the top and bottom ends 624d and 624e of the installing hole 624a of the lower die 624 can be arranged to be both aimed at the second section 40B of the structural layer 40, which means the inner wall of the installing hole 624a of the lower die 624 completely faces the second section 40B of the structural layer 40. In this way, the wearing of the structural layer 40 resulted from the friction between the structural layer 40 and the inner wall of the installing hole 624a of the lower die 624 can be reduced, so that the probe is relatively less possibly fractured. The first section 40A of the structural layer 40 can be still made of a material with relatively higher electrical conductivity, thereby prevented from being damaged by overheat.

In conclusion, the primary technical features of the microelectromechanical probe without the aforesaid head distance in the sixth to eighth preferred embodiments of the invention lies in that the microelectromechanical probe 20 is composed of the pinpoint layer 30, and the structural layer 40 having a relatively greater electrical conductivity than that of the pinpoint layer 30; the top surface 32 of the pinpoint layer 30 is processed by planarization; the pinpoint layer 30 and the structural layer 40 are provided by the cutting process with the cutting face 70 extended from the top surface 43 to the probing end surface 334 and having the curved section 72 and the flat section 74, so that the pinpoint 33 is very thin and the cutting face 70 is effective in light extinction, thereby achieving high recognizability of the pinpoint. The aforesaid technical features are unlimited to be applied to the straight probe as provided in the aforesaid sixth to eighth embodiments, but applicable to the microelectromechanical probe with other shapes, such as the buckling probe, the N-shaped probe, and so on.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A microelectromechanical probe provided with a tail portion, a head portion, and a body portion connecting the tail portion and the head portion, the microelectromechanical probe comprising:
a pinpoint layer having a top surface which is processed by planarization; and
a structural layer disposed on the top surface of the pinpoint layer and provided with a top surface in a way that the top surface of the structural layer and the top surface of the pinpoint layer substantially face a same direction, a first side and a second side both adjoining the top surface of the structural layer, and a cutting face and a front terminal surface both adjoining the first side and the second side, the cutting face descending from the top surface of the structural layer toward the pinpoint layer to the front terminal surface, the cutting face having a front end which is located nearest the top surface of the pinpoint layer within the cutting face, the front terminal surface being extended from the front end to the top surface of the pinpoint layer;
wherein the pinpoint layer has a pinpoint protruding over the front terminal surface of the structural layer and located at the head portion;
wherein within the head portion of the microelectromechanical probe, the pinpoint layer has a hardness greater than that of the structural layer, and the structural layer has an electrical conductivity greater than that of the pinpoint layer.

2. The microelectromechanical probe as claimed in claim 1, wherein the structural layer comprises a first layer and a second layer made of different materials, and the first layer is located between the pinpoint layer and the second layer.

3. The microelectromechanical probe as claimed in claim 1, wherein a perpendicular distance between the front end of the cutting face and the top surface of the pinpoint layer is smaller than a thickness of the pinpoint layer.

4. The microelectromechanical probe as claimed in claim 1, wherein the cutting face is substantially one of a plane, a curved surface and a combination of multiple curved surfaces; the cutting face has at least one cut mark formed by a cutting process; the at least one cut mark is extended from the first side to the second side of the structural layer.

5. A microelectromechanical probe provided with a tail portion, a head portion, and a body portion connecting the tail portion and the head portion, the microelectromechanical probe comprising:
a pinpoint layer having a top surface processed by planarization, a bottom surface opposite to the top surface, a first side and a second side both adjoining the top surface and the bottom surface, and a probing end surface adjoining the first side and the second side and located at the head portion;
a structural layer disposed on the top surface of the pinpoint layer and provided with a top surface in a way that the top surface of the structural layer and the top surface of the pinpoint layer substantially face a same direction, and a first side and a second side both adjoining the top surface of the structural layer, the first side of the structural layer and the first side of the pinpoint layer substantially facing a same direction, and the second side of the structural layer and the second side of the pinpoint layer substantially facing a same direction; and
a cutting face adjoining the first and second sides of the pinpoint layer and the first and second sides of the structural layer and provided with a curved section and a flat section, the curved section curvedly descending from the top surface of the structural layer to the pinpoint layer and having a bottom end located at the pinpoint layer, the flat section being extended from the bottom end of the curved section in parallel to the bottom surface of the pinpoint layer to the probing end surface;
wherein the pinpoint layer has a first thickness defined by the bottom surface and the top surface of the pinpoint layer, and a second thickness defined by the bottom surface of the pinpoint layer and the flat section of the cutting face; the first thickness is greater than the second thickness;
wherein the structural layer has an electrical conductivity greater than that of the pinpoint layer.

6. The microelectromechanical probe as claimed in claim 5, wherein the structural layer comprises a first section and a second section made of different materials; the first section is extended from the tail portion toward the head portion and provided with a connecting end; the second section is extended from the connecting end toward the probing end surface.

7. The microelectromechanical probe as claimed in claim 6, wherein an attachment layer is provided between the structural layer and the pinpoint layer; the second section of the structural layer and the pinpoint layer are made by a same material and connected with each other by the attachment layer.

8. The microelectromechanical probe as claimed in claim 7, wherein the attachment layer and the first section of the structural layer are made by a same material.

9. The microelectromechanical probe as claimed in claim 5, wherein the probing end surface of the pinpoint layer is archedly extended from the first side of the pinpoint layer to the second side of the pinpoint layer.

10. The microelectromechanical probe as claimed in claim 5, wherein the structural layer comprises a first layer and a second layer made of different materials, and the first layer is located between the pinpoint layer and the second layer.

11. The microelectromechanical probe as claimed in claim 10, wherein the pinpoint layer and one of the first layer and the second layer are made by a same material.

12. The microelectromechanical probe as claimed in claim 10, wherein the materials of the first layer and the second layer are different from a material of the pinpoint layer.

13. The microelectromechanical probe as claimed in claim 10, wherein the first layer protrudes beyond the second layer on the first side and the second side of the structural layer.

14. The microelectromechanical probe as claimed in claim 10, wherein a part of the first layer, which is located within the head portion, protrudes beyond a part of the second layer, which is located within the head portion, on the first side and the second side of the structural layer; another part of the first layer, which is located within the tail portion, protrudes beyond another part of the second layer, which is located within the tail portion, on the first side and the second side of the structural layer.

15. The microelectromechanical probe as claimed in claim 5, wherein the first layer protrudes beyond the second layer at a tail end of the tail portion.

16. The microelectromechanical probe as claimed in claim 5, wherein the pinpoint layer protrudes beyond the first side and the second side of the structural layer.

17. The microelectromechanical probe as claimed in claim 5, wherein parts of the pinpoint layer, which are located within the head portion and the tail portion, protrude beyond the first side and the second side of the structural layer.

18. The microelectromechanical probe as claimed in claim 5, wherein the pinpoint layer protrudes beyond the structural layer at a tail end of the tail portion.

19. The microelectromechanical probe as claimed in claim 5, wherein the cutting face has at least one cut mark formed by a cutting process; the cut mark is substantially extended from the first side of one of the pinpoint layer and the structural layer to the second side of one of the pinpoint layer and the structural layer.

20. A probe head comprising:
an upper die;
a lower die; and
a microelectromechanical probe as claimed in claim 5, the tail portion and the head portion of the microelectromechanical probe being inserted through the upper die and the lower die respectively, the cutting face being completely exposed out of the lower die.
